(19) United States
(12) Patent Application Publication
(10) Pub. No.: US 2025/0048870 A1
(43) Pub. Date: Feb. 6, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Qian LI, Beijing (CN); Hongting LU, Beijing (CN); Kezhi LIU, Beijing (CN); Wenjie HU, Beijing (CN)

(21) Appl. No.: 18/578,301

(22) PCT Filed: Aug. 4, 2022
(86) PCT No.: PCT/CN2022/110257

§ 371 Date: Jan. 10, 2024

(30) Foreign Application Priority Data
Aug. 11, 2021 (CN) 202110917744.X

(51) Int. Cl. H10K 59/131; G09G 3/3233; H10K 59/80

(52) U.S. Cl. CPC H10K 59/1315; H10K 59/80522; G09G 3/3233; G09G 2300/0426; G09G 2300/0819; G09G 2300/0842; G09G 2300/0861; G09G 2310/08; G09G 2330/021

(57) ABSTRACT

A display substrate, including a base substrate, multiple light-emitting elements and a first power supply line structure, the base substrate includes a display area and a bezel area on the periphery of the display area; the multiple light-emitting elements are in the display area, and at least one light-emitting element includes an anode, an organic light-emitting layer and a cathode, which are sequentially arranged in a direction away from the base substrate; the first power supply line structure is electrically connected to the cathode and is in the bezel area; the first power supply line structure has at least one first opening; the cathode includes a bezel cathode in the bezel area, the the bezel area has at least one second opening; and an orthographic projection of the first power supply line structure on the base substrate at least partially overlaps with that of the bezel cathode on the base substrate.

### CROSS-REFERENCE TO RELATED APPLICATIONS

The present application is a U.S. National Phase Entry of International Application PCT/CN2022/110257 having an international filing date of Aug. 4, 2022, which claims priority of Chinese Patent Application No. 202110917744.X, filed to the CNIPA on Aug. 11, 2021 and entitled “Display substrate and Display Device”, the contents of which are hereby incorporated herein by reference in their entireties.

### TECHNICAL FIELD

The present disclosure relates to, but is not limited to, the field of display technology, in particular to a display substrate and a display device.

### BACKGROUND

An Organic Light Emitting Diode (OLED) and a Quantum dot Light Emitting Diode (QLED) are active light emitting display devices, which have advantages of self-luminescence, a wide viewing angle, a high contrast ratio, low power consumption, an extremely high response speed, lightness and thinness, bendability, and a low cost, etc.

### SUMMARY

The following is a summary of subject matter described herein in detail. The summary is not intended to limit the scope of protection of the claims.

Embodiments of the present disclosure provide a display substrate and a display device.

In one aspect, some embodiments of the present disclosure provide a display substrate, including a base substrate, a plurality of light emitting elements and a first power supply line structure. The base substrate includes a display area and a bezel area located around the display area. The plurality of light emitting elements are located in the display area, at least one of the light emitting elements includes an anode, an organic light emitting layer, and a cathode arranged sequentially in a direction away from the base substrate. The first power supply line structure is electrically connected to the cathode and located in the bezel area. The first power supply line structure has at least one first opening. The cathode includes a bezel cathode located in the bezel area, the bezel cathode has at least one second opening. An orthographic projection of the first power supply line structure on the base substrate at least partially overlaps with an orthographic projection of the bezel cathode on the base substrate, and an orthographic projection of the at least one first opening on the base substrate at least partially overlaps with an orthographic projection of the at least one second opening on the base substrate.

In some exemplary implementation modes, the first power supply line structure includes a plurality of first repetition units arranged in an array and connected to each other.

In some exemplary implementation modes, the first repetition unit includes: a first main body, a first connection bridge and a second connection bridge formed by extending from opposite sides of the first main body in a first direction, and a third connection bridge and a fourth connection bridge formed by extending from the opposite sides of the first main body in a second direction; and the first direction intersects with the second direction.

In some exemplary implementation modes, a length of each of the first connection bridge and the second connection bridge in the first direction is greater than that in the second direction; a length of each of the third connection bridge and the fourth connection bridge in the first direction is less than that in the second direction.

In some exemplary implementation modes, a length of the first repetition unit in the first direction is substantially the same as a length of the first repetition unit in the second direction.

In some exemplary implementation modes, orthographic projections of the first main body, the first connection bridge, the second connection bridge, the third connection bridge, and the fourth connection bridge on the base substrate are all rectangular.

In some exemplary implementation modes, the first connection bridge and the second connection bridge are substantially symmetrical with respect to a center line of the first main body in the first direction; and the third connection bridge and the fourth connection bridge are substantially symmetrical with respect to a center line of the first main body in the second direction.

In some exemplary implementation modes, the length of the third connection bridge in the first direction is determined according to the following equation:

L2=[(1−TR/0.71)*(25400/P)²−D1*D2−2L1*L3]/(2*L4);
where TR is a light transmittance required by the bezel area, P is a resolution of the display substrate, D1 is a length of the first main body in the second direction, D2 is a length of the first main body in the first direction, L1 is a length of the first connection bridge in the second direction, L3 is a length of the first connection bridge in the first direction, and L4 is a length of the third connection bridge in the second direction.

In some exemplary implementation modes, the bezel cathode is located on a side of the first power supply line structure away from the base substrate; an orthographic projection of a connection area between the bezel cathode and the first power supply line structure on the base substrate is within an orthographic projection of the first main body of the first power supply line structure on the base substrate.

In some exemplary implementation modes, the bezel cathode includes: a plurality of second repetition units; the plurality of second repetition units arranged in the first direction are connected to each other. In an overlapping region between the bezel cathode and the first power supply line structure, an orthographic projection of the first repetition units on the base substrate includes an orthographic projection of the second repetition units on the base substrate.

In some exemplary implementation modes, each second repetition unit includes a second main body, a fifth connection bridge and a sixth connection bridge formed by extending from opposite sides of the second main body in the first direction.

In some exemplary implementation modes, the fifth connection bridge and the sixth connection bridge are substantially symmetrical with respect to a center line of the second repetition unit in the first direction.

In some exemplary implementation modes, orthographic projections of the second main body, the fifth connection bridge, and the sixth connection bridge on the base substrate are all rectangular.

In some exemplary implementation modes, the second repetition unit further includes: a seventh connection bridge and an eighth connection bridge formed by extending from opposite sides of the second main body in the second direction; and the plurality of second repetition units are connected in a mesh.

In some exemplary implementation modes, the cathode further includes: a display cathode located in the display area, the display cathode includes: a plurality of third repetition units arranged in an array. A shape, size and connection relationship of the third repetition units of the display cathode are substantially the same as shape, size and connection relationship of the second repetition units of the bezel cathode.

In some exemplary implementation modes, each third repetition unit includes a third main body, a ninth connection bridge and a tenth connection bridge formed by extending from opposite sides of the third main body in the first direction.

In some exemplary implementation modes, the display substrate further includes: a plurality of auxiliary electrodes located in the display area. The plurality of auxiliary electrodes are electrically connected to the plurality of third repetition units of the display cathode. The plurality of auxiliary electrodes are electrically connected to the first power supply line structure of the bezel area via a first connection line.

In some exemplary implementation modes, each auxiliary electrode includes: a first sub-auxiliary electrode disposed in a same layer as the first power supply line structure, and a second sub-auxiliary electrode disposed in a same layer as the anode of the light emitting element, the first sub-auxiliary electrode is electrically connected to the second sub-auxiliary electrode. The third repetition unit is electrically connected to the second sub-auxiliary electrode and the first sub-auxiliary electrode.

In some exemplary implementation modes, in the display area, the plurality of first sub-auxiliary electrodes are arranged in an array and connected by a fourth connection line and a fifth connection line; the plurality of second sub-auxiliary electrodes are arranged in an array. An orthographic projection of the second sub-auxiliary electrodes on the base substrate covers an orthographic projection of the first sub-auxiliary electrodes on the base substrate.

In some exemplary implementation modes, orthographic projections of the first sub-auxiliary electrodes and the second sub-auxiliary electrodes on the base substrate are all rectangular.

In some exemplary implementation modes, the first connection line extends in the second direction, the first connection line is electrically connected to the first main body of the first power supply line structure. The bezel cathode is provided on a side of the first connection line away from the base substrate, and an orthographic projection of the first connection line on the base substrate overlaps with the orthographic projection of the bezel cathode on the base substrate.

In some exemplary implementation modes, the bezel area includes an upper bezel provided with a second power supply line structure, the second power supply line structure includes a plurality of fourth repetition units arranged in an array. A shape, size and connection relationship of the fourth repetition units are substantially the same as shape, size and connection relationship of the first repetition units of the first power supply line structure of the upper bezel. The orthographic projection of the second repetition units on the base substrate overlaps with an orthographic projection of the fourth repetition units on the base substrate.

In some exemplary implementation modes, the display area is provided with a plurality of power supply connection blocks; the second power supply line structure is electrically connected to the power supply connection blocks of the display area through a second connection line. The second connection line has a straight part and a bent part, a plurality of data lines are provided on a side of the second connection line close to the base substrate, an orthographic projection of the second connection line on the base substrate does not overlap with an orthographic projection of the plurality of data lines on the base substrate. An orthographic projection of a virtual extension line of the straight part of the second connection line on the base substrate overlaps with the orthographic projection of the data lines on the base substrate.

In some exemplary implementation modes, each power supply connection block includes a first sub-power supply connection block and a second sub-power supply connection block which are stacked and electrically connected to each other, an orthographic projection of the first sub-power supply connection block on the base substrate has a shape of a strip extending in the second direction, and an orthographic projection of the second sub-power supply connection block on the base substrate includes the orthographic projection of the first sub-power supply connection block on the base substrate.

In another aspect, an embodiment of the present disclosure provides a display device, which includes the aforementioned display substrate.

After the drawings and the detailed descriptions are read and understood, the other aspects may be comprehended.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a minimum recognition distance for human eye.

FIG. 2 is a schematic diagram of a display substrate according to at least one embodiment of the present disclosure.

FIG. 3 is a schematic diagram of a structure of a display substrate according to at least one embodiment of the present disclosure.

FIG. 4 is an equivalent circuit diagram of a pixel circuit according to at least one embodiment of the present disclosure.

FIG. 5 is an operating timing diagram of the pixel circuit shown in FIG. 4.

FIG. 6 is a schematic partial view of a cathode according to at least one embodiment of the present disclosure.

FIG. 7 is a schematic partial plan view of a display area according to at least one embodiment of the present disclosure.

FIG. 8 is a schematic partial cross-sectional view along a O-O′ direction in FIG. 7.

FIG. 9 is a schematic partial sectional view along an R-R′ direction in FIG. 7.

FIG. 10 is a schematic partial plan view of a display area after a semiconductor layer is formed according to at least one embodiment of the present disclosure.

FIG. 11 is a schematic partial plan view of a display area after a first conductive layer is formed according to at least one embodiment of the present disclosure.

FIG. 12 is a schematic partial plan view of a display area after a second conductive layer is formed according to at least one embodiment of the present disclosure.

FIG. 13 is a schematic partial plan view of a display area after a third insulating layer is formed according to at least one embodiment of the present disclosure.

FIG. 14 is a schematic partial plan view of a display area after a third conductive layer is formed according to at least one embodiment of the present disclosure.

FIG. 15 is a schematic partial plan view of a display area after a fourth conductive layer is formed according to at least one embodiment of the present disclosure.

FIG. 16 is a schematic partial view of a region A1 in FIG. 2.

FIG. 17 is a schematic diagram of a fourth conductive layer in FIG. 16.

FIG. 18 is a schematic partial view of a region A2 in FIG. 2.

FIG. 19 is a schematic diagram of a fourth conductive layer in FIG. 18.

FIG. 20 is a schematic partial enlarged view of a region S2 in FIG. 17.

FIG. 21 is a schematic enlarged view of a region S1 in FIG. 16.

FIG. 22 is a schematic plan view of a first repetition unit and a second repetition unit according to at least one embodiment of the present disclosure.

FIG. 23 is a schematic plan view of a first repetition unit according to at least one embodiment of the present disclosure.

FIG. 24 is a schematic plan view of a second repetition unit according to at least one embodiment of the present disclosure.

FIG. 25 is a schematic partial cross-sectional view along a Q-Q′ direction in FIG. 21.

FIG. 26 is another schematic partial cross-sectional view taken along the Q-Q′ direction in FIG. 21.

FIG. 27 is another schematic plan view of a first repetition unit and a second repetition unit according to at least one embodiment of the present disclosure.

FIG. 28 is another schematic plan view of a bezel area according to at least one embodiment of the present disclosure.

FIG. 29 is another schematic plan view of a first repetition unit and a second repetition unit according to at least one embodiment of the present disclosure.

FIG. 30 is another schematic plan view of a second repetition unit according to at least one embodiment of the present disclosure.

FIG. 31 is another schematic partial view of a cathode according to at least one embodiment of the present disclosure.

FIG. 32 is another schematic partial view of a cathode according to at least one embodiment of the present disclosure.

FIG. 33 is a schematic diagram of a display device according to at least one embodiment of the present disclosure.

### DETAILED DESCRIPTION

The embodiments of the present disclosure will be described below with reference to the drawings in detail. Implementation modes may be practiced in various different forms. Those of ordinary skills in the art may easily understand such a fact that implementation modes and contents may be transformed into other forms without departing from the purpose and scope of the present disclosure. Therefore, the present disclosure should not be explained as being limited to the contents recorded in the following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation mode of the present disclosure is not necessarily limited to the size, and a shape and a size of one or more components in the drawings do not reflect an actual scale. In addition, the accompanying drawings schematically illustrate ideal examples, and an implementation mode of the present disclosure is not limited to the shapes, numerical values, or the like shown in the drawings.

Ordinal numerals “first”, “second”, “third”, etc., in the specification are set not to form limitations on numbers but only to avoid the confusion between constituent elements. In the present disclosure, “a plurality/multiple” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction according to which the constituent elements are described. Therefore, appropriate replacements based on situations are allowed, which are not limited to the expressions in the specification.

In the specification, unless otherwise specified and defined, terms “mounting”, “mutual connection”, and “connection” should be understood in a broad sense. For example, a connection may be a fixed connection, a detachable connection, or an integrated connection; it may be a mechanical connection or an electrical connection; it may be a direct connection, an indirect connection through a middleware, or an internal communication between two components. Those of ordinary skills in the art may understand meanings of the above-mentioned terms in the present disclosure according to situations.

In the specification, a transistor refers to an element which at least includes three terminals, i.e., a gate (gate electrode), a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain electrode and a second electrode may be a source electrode, or, a first electrode may be a source electrode and a second electrode may be a drain electrode. In addition, the gate may also be referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “electrical connection” includes connection of constituent elements through an element with a certain electrical effect. The “element with the certain electrical effect” is not particularly limited as long as electrical signals between the connected constituent elements may be transmitted. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is −10° or more and 100 or less, and thus also includes a state in which the angle is −5° or more and 5° or less. In addition, “perpendicular” refers to a state in which an angle formed by two straight lines is 800 or more and 100° or less, and thus also includes a state in which the angle is 850 or more and 950 or less.

In the present disclosure, “about” and “substantially” refer to that a boundary is not defined strictly and a case within a range of process and measurement errors is allowed. In the present disclosure, “substantially the same” refers to a case where values differ by less than 10%.

Using characteristics of OLED display technology, an OLED display panel can meet requirements of transparent display. Typically, an OLED display panel includes a plurality of light emitting elements, each of which includes an anode, a cathode, and an organic light emitting layer disposed between the anode and the cathode. Light transmittance is an important parameter for transparent display. The light transmittance of the cathode material is about 50% to 60%, which will significantly reduce the light transmittance of the transparent display panel. In order to improve the light transmittance, a patterned cathode design is generally used, so that the cathode material is only retained in pixel areas, while the cathode material in the transparent area between the pixel areas is removed. The patterned cathode also needs to be lapped with a VSS signal line in the bezel area to achieve circuit connectivity.

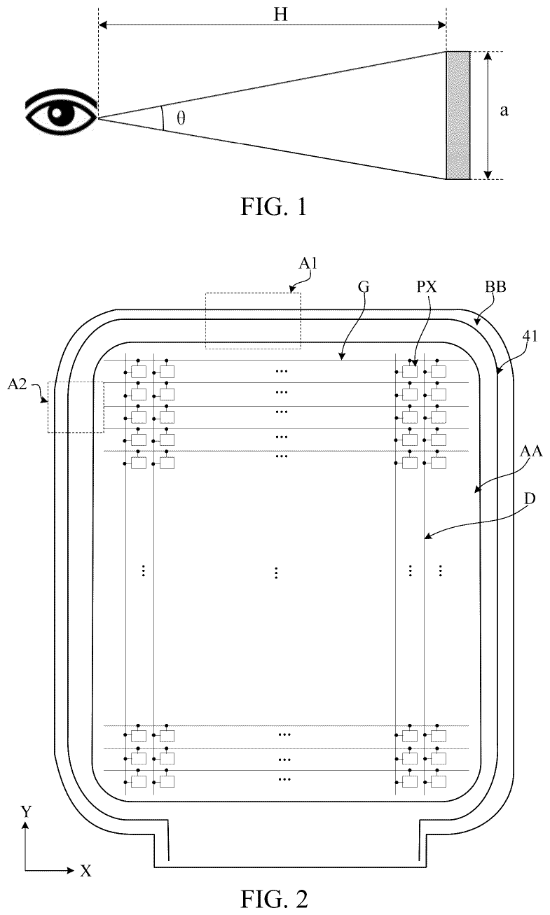

FIG. 1 is a schematic diagram of a minimum recognition distance for human eye. As shown in FIG. 1, a minimum resolution angle θ for a human eye is 1′. Depending on different application environments, a distance H between an object and the human eye varies, resulting in a different minimum recognition distance a for the human eye, where a=2*H*tan(θ/2). Table 1 lists minimum recognition distances for the human eye in different application environments.

TABLE 1

| | Distance H between an | Minimum recognition |
|---|---|---|
| Application | object and the human eye | distance a (unit: |
| environment | (unit: centimeter (cm) | micron (um)) |
| Mobilephone | 25 | 70 |
| application | | |
| environment | | |
| in-vehicle | 70 | 200 |
| environment | | |

As can be seen from Table 1, when the use environment is an in-vehicle environment and a width of wiring is less than 200 um, it cannot be recognized by the human eye. When the use environment is a mobilephone application environment and the width of the wiring is less than 70 um, it cannot be recognized by the human eye. The width represents a length in a direction perpendicular to an extension direction of the wiring. However, the current design width of VSS signal lines in the bezel area of the display substrate is large (for example, greater than 200 microns), which will affect transparency of the bezel area and fail to realize fully transparent products.

At least one embodiment of the present disclosure provides a display substrate including a base substrate, a plurality of light emitting elements, and a first power supply line structure. The base substrate includes a display area and a bezel area located around the display area. The plurality of light emitting elements are located in the display area, and at least one light emitting element includes an anode, an organic light emitting layer, and a cathode arranged sequentially in a direction away from the base substrate. The first power supply line structure is electrically connected to the cathode and is located in the bezel area. The first power supply line structure has at least one first opening. The cathode includes a bezel cathode located in the bezel area, and the bezel cathode has at least one second opening. An orthographic projection of the first power supply line structure on the base substrate is at least partially overlapped with an orthographic projection of the bezel cathode on the base substrate, and an orthographic projection of at least one first opening on the base substrate is at least partially overlapped with an orthographic projection of the at least one second opening on the base substrate. In some examples, the first power supply line structure is a VSS signal line that can continuously provide a low-level signal.

The display substrate according to this embodiment can achieve transparency of the first power supply line structure and the bezel cathode by patterning the first power supply line structure and the bezel cathode in the bezel area, thereby enhancing the light transmittance of the bezel area to support realization of a fully transparent display product.

In some exemplary implementation modes, the first power supply line structure includes a plurality of first repetition units arranged in an array and connected to each other. The plurality of first repetition units of the first power supply line structure of the bezel area of this exemplary embodiment are arranged in a regular pattern. However, this embodiment is not limited thereto. For example, the plurality of first repetition units of the first power supply line structure of the bezel area may be arranged irregularly.

In some exemplary implementation modes, each first repetition unit includes a first main body, a first connection bridge and a second connection bridge formed by extending from opposite sides of the first main body in a first direction respectively, and a third connection bridge and a fourth connection bridge formed by extending from opposite sides of the first main body in a second direction. Among them, the first direction intersects with the second direction. In some examples, the first direction and the second direction are perpendicular to each other.

In some exemplary implementation modes, the bezel cathode is located on a side of the first power supply line structure away from the base substrate. An orthographic projection of a connection area between the bezel cathode and the first power supply line structure on the base substrate is located in an orthographic projection of the first main body of the first power supply line structure on the base substrate. However, this embodiment is not limited thereto.

In some exemplary implementation modes, the bezel cathode includes a plurality of second repetition units. The plurality of second repetition units arranged in the first direction are connected to each other. An orthographic projection of the first repetition units on the base substrate may include an orthographic projection of the second repetition units on the base substrate in an overlapping region between the bezel cathode and the first power supply line structure. In this exemplary implementation mode, in the overlapping region between the first power supply line structure and the bezel cathode, loss of light transmittance can be reduced by making a size of the first repetition unit of the first power supply line structure greater than or equal to a size of the second repetition unit of the bezel cathode.

In some exemplary implementation modes, the cathode further includes a display cathode located in the display area. The display cathode includes a plurality of third repetition units arranged in an array. Shape, size and connection relationship of the third repetition units are substantially the same as those of the second repetition units of the bezel cathode. In this example, the cathode includes the display cathode located in the display area and the bezel cathode located in the bezel area. In this exemplary implementation mode, the light transmittance of the display area can be enhanced by patterning the display cathode of the display area. However, this embodiment is not limited thereto. For example, the display cathode may be of a full-face structure, that is, a display product that only realizes the transparency of the bezel.

In some exemplary implementation modes, the display substrate further includes a plurality of auxiliary electrodes located in the display area. The plurality of auxiliary electrodes are electrically connected to the plurality of third repetition units of the display cathode and are electrically connected to the first power supply line structure of the bezel area through a first connection line. In this example, an electrical connection between the display cathode and the first power supply line structure can be achieved by the auxiliary electrodes. In some examples, an auxiliary electrode may include a first sub-auxiliary electrode and a second sub-auxiliary electrode that are stacked and electrically connected to each other. However, this embodiment is not limited thereto.

In some exemplary implementation modes, the bezel area includes an upper bezel provided with a second power supply line structure. The second power supply line structure includes a plurality of fourth repetition units arranged in an array, the shape, size and connection relationship of the fourth repetition units are substantially the same as the shape, size and connection relationship of the first repetition units of the first connection line structure of the upper bezel. The orthographic projection of the second repetition units on the base substrate overlaps with an orthographic projection of the fourth repetition units on the base substrate. In some examples, the second power supply line structure may be a VDD signal line that may continuously provide a high-level signal. However, this embodiment is not limited thereto.

In some exemplary implementation modes, the display area is provided with a plurality of power supply connection blocks. The second power supply line structure is electrically connected to the power supply connection blocks of the display area through a second connection line. The second connection line has a straight part and a bent part. A plurality of data lines are provided on a side of the second connection line close to the base substrate. An orthographic projection of the second connection line on the base substrate does not overlap with an orthographic projection of the plurality of data lines on the base substrate. An orthographic projection of a virtual extension line of the straight part of the second connection line on the base substrate overlaps with the orthographic projection of the data lines on the base substrate. In this example, the second connection line with a bending design can be staggered from the data lines of an adjacent layer to avoid signal interference.

Solutions of the embodiments will be described below through some examples.

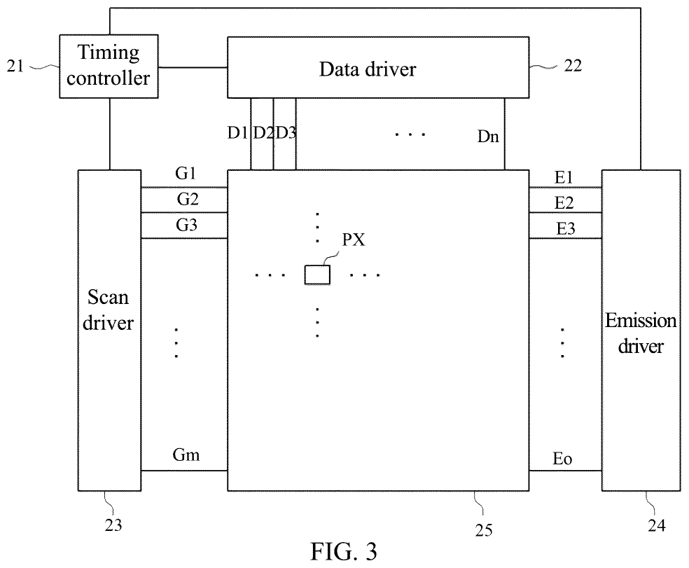

FIG. 2 is a schematic diagram of a display substrate according to at least one embodiment of the present disclosure. In some exemplary implementation modes, as shown in FIG. 2, the display substrate according to this exemplary embodiment includes a base substrate. The base substrate includes a display area AA and a bezel area BB located around the display area AA. In some examples, the bezel area BB may include an upper bezel, a lower bezel, a left bezel and a right bezel of the base substrate. However, this embodiment is not limited thereto.

In some exemplary implementation modes, the display substrate may be in an approximately rectangular shape. As shown in FIG. 2, the display substrate may include a pair of short sides parallel to each other in a second direction X and a pair of long sides parallel to each other in a first direction Y. That is, a length of the display substrate in the second direction X is smaller than that in the first direction Y. The second direction X and the first direction Y intersect with each other, for example, the second direction X is perpendicular to the first direction Y. However, this embodiment is not limited thereto. In some exemplary implementation modes, the base substrate may be in a shape of a closed polygon including linear sides, a circle or ellipse including a curved side, or a semi-circle or semi-ellipse including a linear side and a curved side, or the like. In some examples, when the base substrate has a linear edge, at least some corners of the base substrate may be curved. When the base substrate is in a shape of a rectangle, a portion at a position where adjacent linear edges intersect with each other may be replaced by a curve with a predetermined curvature. Among them, the curvature may be set according to different positions of the curve. For example, the curvature may be changed according to a starting position of the curve, a length of the curve, etc.

In some exemplary implementation modes, as shown in FIG. 2, the display area AA includes at least a plurality of sub-pixels PX, a plurality of gate lines G and a plurality of data lines D. The plurality of gate lines G extend along the second direction X and are arranged sequentially along the first direction Y. The plurality of data lines D extend in the first direction Y and are arranged sequentially in the second direction X. Orthographic projections of the plurality of gate lines G on the base substrate and orthographic projections of the plurality of data lines D on the base substrate intersect to form a plurality of sub-pixel regions, and one of the sub-pixels PX is disposed in each sub-pixel region. The plurality of data lines D are electrically connected to the plurality of sub-pixels PX and the plurality of data lines D are configured to provide data voltages to the plurality of sub-pixels PX. The plurality of gate lines G are electrically connected to the plurality of sub-pixels PX and the plurality of gate lines G are configured to provide gate control signals to the plurality of sub-pixels PX. However, this embodiment is not limited thereto.

In some exemplary implementation modes, one pixel unit may include three sub-pixels, i.e., a red sub-pixel, a green sub-pixel, and a blue sub-pixel respectively. However, this embodiment is not limited thereto. In some examples, one pixel unit may include four sub-pixels, and the four sub-pixels are a red sub-pixel, a green sub-pixel, a blue sub-pixel, and a white sub-pixel respectively.

In some exemplary implementation modes, the display substrate of this embodiment may be a transparent display substrate. Adjacent pixel units can have a light-transmitting area between them to achieve transparent display. However, this embodiment is not limited thereto.

In some exemplary implementations, a shape of a sub-pixel may be a rectangle, a rhombus, a pentagon, or a hexagon. When one pixel unit includes three sub-pixels, the three sub-pixels may be arranged side by side horizontally, side by side vertically, or in a delta-shaped form. When one pixel unit includes four sub-pixels, the four sub-pixels may be arranged side by side horizontally, side by side vertically, or in a shape of a square. However, this embodiment is not limited thereto.

In some exemplary implementation modes, a sub-pixel may include a pixel circuit and a light emitting element electrically connected to the pixel circuit. The pixel circuit may include a plurality of transistors and at least one capacitor. For example, the pixel circuit may be of a 3T1C (three transistors and one capacitor) structure, a 7T1C (seven transistors and one capacitor) structure, or a 5T1C (five transistors and one capacitor) structure. In some examples, the light emitting element may be an OLED device. The light emitting element may include an anode, a cathode and an organic light emitting layer disposed between the anode and the cathode. The anode of the light emitting element may be electrically connected to a corresponding pixel circuit. However, this embodiment is not limited thereto.

In some exemplary implementation modes, as shown in FIG. 2, the bezel area BB is provided with a first power supply line structure 41. The lower bezel of the bezel area BB may include a signal access region. In the bezel area BB, the first power supply line structure 41 may be disposed around the display area AA and extend to the signal access region to be connected to a drive chip disposed within the signal access region to receive a low-level signal from the drive chip. However, this embodiment is not limited thereto. In some examples, the first power supply line structure may extend to a bonding region of the lower bezel and be connected to a bonding electrode within the bonding region to receive a low-level signal from an external control circuit.

FIG. 3 is a schematic diagram of a structure of a display substrate according to at least one embodiment of the present disclosure. In some exemplary implementation modes, as shown in FIG. 3, the display substrate may include a timing controller 21, a data driver 22, a scan driver 23, an emission driver 24 and a sub-pixel array 25. The sub-pixel array 25 located in the display area AA may include a plurality of sub-pixels PX arranged regularly. The scan driver 23 is configured to supply a scan signal to the sub-pixels along a scan line. The data driver 22 is configured to supply data voltages to the sub-pixels along a data line. The emission driver 24 is configured to supply a light emitting control signal to the sub-pixels along a light emitting control line. The timing controller 21 is configured to control the scan driver 23, the emission driver 24 and the data driver 22.

In some exemplary implementation modes, as shown in FIG. 3, the timing controller 21 may provide a gray-scale value and a control signal adaptable to a specification of the data driver 22 to the data driver 22. The timing controller 21 may provide a clock signal and a start signal adaptable to a specification of the scan driver 23 to the scan driver 23. The timing controller 21 may provide a clock signal and a scan start signal adaptable to a specification of the emission driver 24 to the emission driver 24. The data driver 22 may generate a data voltage, which will be provided to data lines D1 to Dn, using the gray-scale value and the control signal received from the timing controller 21. For example, the data driver 22 may sample the gray-scale value using the clock signal and apply the data voltage corresponding to the gray-scale value to the data lines D1 to Dn by using a sub-pixel row as a unit. The scan driver 23 may receive the clock signal, the scan start signal, etc., from the timing controller 21 to generate a scan signal to be provided for scanning lines G1 to Gm. For example, the scan driver 23 may sequentially provide a scan signal with a turn-on level pulse to a scan line. In some examples, the scan driver 23 may include a shift register and sequentially transmit the scan start signal provided in form of a turn-on level pulse to a next-stage circuit to generate the scan signal under control of the clock signal. The emission driver 24 may receive the clock signal, an emission stop signal, etc., from the timing controller 21 to generate light emitting control signals to be supplied to light emitting control lines E1 to Eo. For example, the emission driver 24 may sequentially provide light emitting control signals with an off-level pulse to light emitting control lines. The emission driver 24 may include a shift register to sequentially transmit the emission stop signal provided in form of a cut-off level pulse to a next-stage circuit to generate an emission signal under the control of the clock signal. Among them, n, m, and o are all natural numbers.

In some exemplary implementation modes, the scan driver 23 and the emission driver 24 may be directly arranged on the base substrate. For example, the scan driver 23 and the emission driver 24 may be provided in the bezel area (for example the left bezel and the right bezel) on the left and right sides of the display area AA. For example, the scan driver 23 and the emission driver 24 may be located on a side of the first power supply line structure 41 close to the display area AA. In some examples, the scan driver 23 and the emission driver 24 may be formed together with the sub-pixels in a process of forming the sub-pixels. However, positions or formation manner of the scan driver 23 and the emission driver 24 are not limited in this embodiment. In some examples, the scan driver 23 and the emission driver 24 may be arranged on an independent chip or printed circuit board to be connected to a bonding pad or welding pad formed on the base substrate.

In some exemplary implementation modes, the data driver 22 may be disposed on a separate chip or printed circuit board so as to be connected to a sub-pixel through a signal access pin provided in a signal access region of the bezel area of the base substrate. For example, the data driver 22 may be formed and disposed in the signal access region using a chip on glass, a chip on plastic, a chip on film, etc., so as to be connected to the signal access pin on the base substrate. The timing controller 21 may be provided separately from the data driver 22 or provided integrally with the data driver 22. However, this embodiment is not limited thereto.

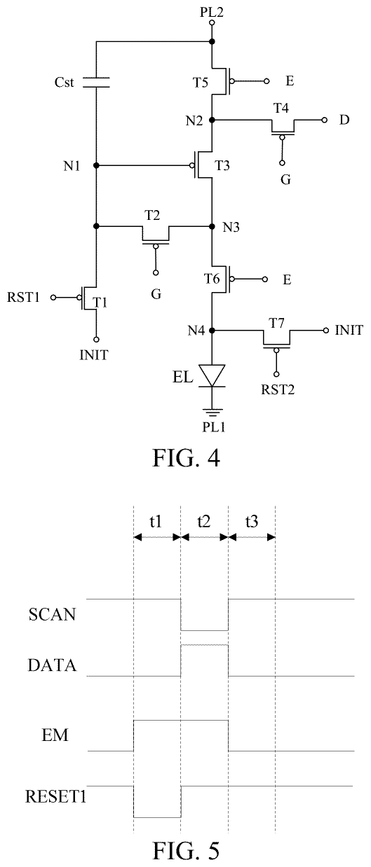

FIG. 4 is an equivalent circuit diagram of a pixel circuit according to at least one embodiment of the present disclosure. FIG. 5 is an operating timing diagram of the pixel circuit shown in FIG. 4.

In some exemplary implementation modes, as shown in FIG. 4, the pixel circuit of this exemplary embodiment may include: six switching transistors (T1, T2, and T4 to T7), one drive transistor T3, and one storage capacitor Cst. The six switching transistors are respectively a data writing transistor T4, a threshold compensation transistor T2, a first light emitting control transistor T5, a second light emitting control transistor T6, a first reset transistor T1, and a second reset transistor T7. A light emitting element EL includes an anode, a cathode, and an organic light emitting layer disposed between the anode and the cathode.

In some exemplary implementation, the drive transistor and the six switching transistors may be P-type transistors or may be N-type transistors. Using a same type of transistors in a pixel circuit may simplify a process flow, reduce a process difficulty of a display substrate, and improve a yield of products. In some exemplary implementation, the drive transistor and the six switching transistors may include a P-type transistor and an N-type transistor.

In some exemplary implementation, Low Temperature Poly-Silicon thin film transistors, or oxide thin film transistors, or a Low Temperature Poly-Silicon thin film transistor and an oxide thin film transistor may be used for the drive transistor and the six switching transistors. An active layer of a low temperature poly-silicon thin film transistor is made of Low Temperature Poly-Silicon (LTPS), and an active layer of an oxide thin film transistor is made of an oxide semiconductor (Oxide). A Low-temperature Poly-Silicon thin film transistor has advantages such as a high mobility and fast charging, while an oxide thin film transistor has an advantage such as a low leakage current. The Low Temperature Poly-Silicon thin film transistor and the oxide thin film transistor are integrated on one display substrate to form a Low Temperature Polycrystalline Oxide (LTPO) display substrate, and advantages of both the Low Temperature Poly-Silicon thin film transistor and the oxide thin film transistor may be utilized to achieve low frequency drive, reduce power consumption, and improve display quality.

In some exemplary implementation modes, as shown in FIG. 4, a pixel circuit is electrically connected to a scan line G, a data line D, a first power supply line PL1, a second power supply line PL2, a light emitting control line E, an initial signal line INIT, a first reset control line RST1 and a second reset control line RST2. In some examples, the first power supply line PL1 is configured to provide a constant first voltage signal VSS to the pixel circuit, and the second power supply line PL2 is configured to provide a constant second voltage signal VDD to the pixel circuit, and the second voltage signal VDD is greater than the first voltage signal VSS. The scan line G is configured to provide a scan signal SCAN to the pixel circuit, the data line D is configured to provide a data signal DATA to the pixel circuit, the light emitting control line E is configured to provide a light emitting control signal EM to the pixel circuit, the first reset control line RST1 is configured to provide a first reset control signal RESET1 to the pixel circuit, and the second reset control line RST2 is configured to provide a second reset signal RESET2 to the pixel circuit. In some examples, in a row of pixel circuits, a second reset control line RST2 may be connected to a scan line G to be input with a scan signal SCAN. That is, a second reset signal RESET2(n) received by a pixel circuit of an n-th row is a scan signal SCAN(n) received by the pixel circuit of the n-th row. However, this embodiment is not limited thereto. For example, the second reset control signal line RST2 may be inputted with a second reset control signal RESET2 different from the scan signal SCAN. In some examples, in pixel circuits of the n-th row, a first reset control line RST1 may be connected to a scan line G of the pixel circuits of an (n−1)-th row to be inputted with a scan signal SCAN (n−1), that is, a first reset control signal RESET1(n) is the same as the scan signal SCAN (n−1). Thus, signal lines of the display substrate may be reduced, and a narrow bezel of the display substrate can be achieved.

In some exemplary implementation, as shown in FIG. 4, the drive transistor T3 is electrically connected to the light emitting element EL, and outputs a drive current to drive the light emitting element EL to emit light under control of the scan signal SCAN, the data signal DATA, the first voltage signal VSS, the second voltage signal VDD and etc. A gate of the data writing transistor T4 is electrically connected to the scan line G, a first electrode of the data writing transistor T4 is electrically connected to the data line D, and a second electrode of the data writing transistor T4 is electrically connected to a first electrode of the drive transistor T3. A gate of the threshold compensation transistor T2 is electrically connected to the scan line G, a first electrode of the threshold compensation transistor T2 is electrically connected to a gate of the drive transistor T3, and a second electrode of the threshold compensation transistor T2 is electrically connected to a second electrode of the drive transistor T3. A gate of the first light emitting control transistor T5 is electrically connected to the light emitting control line E, a first electrode of the first light emitting control transistor T5 is electrically connected to the second power supply line PL2, and a second electrode of the first light emitting control transistor T5 is electrically connected to the first electrode of the drive transistor T3. A gate of the second light emitting control transistor T6 is electrically connected to the light emitting control line E, a first electrode of the second light emitting control transistor T6 is electrically connected to the second electrode of the drive transistor T3, and a second electrode of the second light emitting control transistor T6 is electrically connected to an anode of the light emitting element EL. The first reset transistor T1 is electrically connected to the gate of the drive transistor T3 and configured to reset the gate of the drive transistor T3, and the second reset transistor T7 is electrically connected to the anode of the light emitting element EL and configured to reset the anode of the light emitting element EL. A gate of the first reset transistor T1 is electrically connected to the first reset control line RST1, a first electrode of the first reset transistor T1 is electrically connected to an initial signal line INIT, and a second electrode of the first reset transistor T1 is electrically connected to the gate of the drive transistor T3. A gate of the second reset transistor T7 is electrically connected to the second reset control line RST2, a first electrode of the second reset transistor T7 is electrically connected to the initial signal line INIT, and a second electrode of the second reset transistor T7 is electrically connected to the anode of the light emitting element EL. A first electrode of the storage capacitor Cst is electrically connected to the gate of the drive transistor T3, and a second electrode of the storage capacitor Cst is electrically connected to the second power supply line PL2. In this example, a first node N1 is a connection point of the storage capacitor Cst, the first reset transistor T1, the drive transistor T3, and the threshold compensation transistor T2. A second node N2 is a connection point of the first light emitting control transistor T5, the data writing transistor T4, and the drive transistor T3. A third node N3 is a connection point of the drive transistor T3, the threshold compensation transistor T2, and the second light emitting control transistor T6. A fourth node N4 is a connection point of the second light emitting control transistor T6, the second reset transistor T7, and the light emitting element EL.

A working process of the pixel circuit shown in FIG. 4 will be described below with reference to FIG. 5. The description is given by taking a case in which a plurality of transistors included in the pixel circuit shown in FIG. 4 are all P-type transistors as an example.

In some exemplary implementation modes, as shown in FIG. 4 and FIG. 5, during one frame of display period, the working process of the pixel circuit may include a first stage t1, a second stage t2, and a third stage t3.

In the first stage t1, which is referred to as a reset stage, a first reset control signal RESET1 provided by the first reset control line RST1 is a low-level signal, so that the first reset transistor T1 is turned on, and an initial signal Vinit provided by the initial signal line INIT is provided to the first node N1 to initialize the first node N1 and clear an original data voltage in the storage capacitor Cst. A scan signal SCAN provided by the scan line G is a high-level signal, and a light emitting control signal EM provided by the light emitting control line E is a high-level signal, such that the data writing transistor T4, the threshold compensation transistor T2, the first light emitting control transistor T5, the second light emitting control transistor T6, and the second reset transistor T7 are turned off. In this stage, the light emitting element EL does not emit light.

In a second stage t2, which is referred to as a data writing stage or a threshold compensation stage, the scan signal SCAN provided by the scan line G is a low-level signal, the first reset control signal RESET1 provided by the first reset control line RST1 and the light emitting control signal EM provided by the light emitting control line E are both high-level signals, and the data line DT outputs a data signal DATA. In this stage, the second electrode of the storage capacitor Cst is at a low level, so that the drive transistor T3 is turned on. The scan signal SCAN is a low-level signal, so that the threshold compensation transistor T2, the data writing transistor T4, and the second reset transistor T7 are turned on. The threshold compensation transistor T2 and the data writing transistor T4 are turned on, so that a data voltage Vdata output by the data line D is provided to the first node N2 through the second node N2, the turned-on drive transistor T3, the third node N3, and the turned-on threshold compensation transistor T2, and the storage capacitor Cst is charged with a difference between the data voltage Vdata output by the data line D and a threshold voltage of the drive transistor T3. A voltage of the second plate of the storage capacitor Cst (that is, the first node N1) is Vdata−|Vth|, wherein Vdata is the data voltage output by the data line D, and Vth is the threshold voltage of the drive transistor T3. The second reset transistor T7 is turned on, so that an initial signal Vinit provided by the initial signal line INIT is provided to the anode of the light emitting element EL to initialize (reset) the anode of the light emitting element EL and clear a pre-stored voltage therein, so as to complete initialization, thereby ensuring that the light emitting element EL does not emit light. The first reset control signal RESET1 provided by the first reset control line RST1 is the high-level signal, so that the first reset transistor T1 is turned off. The light emitting control signal EM provided by the light emitting control signal line E is the high-level signal, such that the first light emitting control transistor T5 and the second light emitting control transistor T6 are turned off.

In the third stage t3, which is referred to as a light emitting stage, the light emitting control signal EM provided by the light emitting control signal line E is a low-level signal, and the scan signal SCAN provided by the scan line G and the first reset control signal RESET1 provided by the first reset control line RST1 are high-level signals. The light emitting control signal EM provided by the light emitting control signal line E is the low-level signal, so that the first light emitting control transistor T5 and the second light emitting control transistor T6 are turned on, and a second voltage signal VDD output by the second power supply line PL2 provides a drive voltage to the anode of the light emitting element EL through the turned-on first light emitting control transistor T5, the drive transistor T3, and the second light emitting control transistor T6 to drive the light emitting element EL to emit light.

In a drive process of the pixel circuit, a drive current flowing through the drive transistor T3 is determined by a voltage difference between the gate and the first electrode of the drive transistor M3. Because the voltage of the first node N1 is Vdata−|Vth|, the drive current of the drive transistor T3 is as follows.

$$I = K * {( V gs - V th )}^{2} = K * {[ ( V DD - V data + \vert V th \vert ) - V th ]}^{2} = K * {[ ( V DD - V data ) ]}^{2} ;$$

Among them, I is the drive current flowing through the drive transistor T3, that is, the drive current for driving the light emitting element EL; K is a constant; Vgs is the voltage difference between the gate and the first electrode of the drive transistor T3; Vth is the threshold voltage of the drive transistor T3; Vdata is the data voltage output by the data line D; and VDD is the second voltage signal output by the second power supply line PL2.

It may be seen from the above formula that a current flowing through the light emitting element EL has nothing to do with the threshold voltage of the drive transistor T3. Therefore, the pixel circuit of this embodiment can better compensate the threshold voltage of the drive transistor T3.

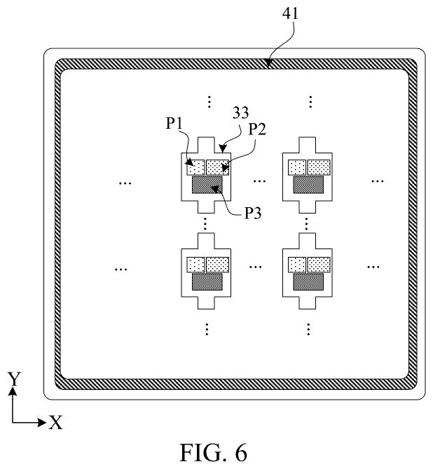

FIG. 6 is a partial plan view of a cathode of a display substrate according to at least one embodiment of the present disclosure. In some exemplary implementation modes, as shown in FIG. 6, a plurality of pixel units are arranged in the display area, and one pixel unit may include a first sub-pixel P1, a second sub-pixel P2, and a third sub-pixel P3. The first sub-pixel P1, the second sub-pixel P2, and the third sub-pixel P3 included in the pixel unit may be arranged in a delta-shaped form. In some examples, the first sub-pixel P1 may be a green sub-pixel, the second sub-pixel P2 may be a red sub-pixel, and the third sub-pixel P3 may be a blue sub-pixel. However, this embodiment is not limited thereto.

In some exemplary implementation modes, as shown in FIG. 6, a cathode of the display substrate may include a display cathode 33 located in the display area and a bezel cathode located in the bezel area. The display cathode 33 may include cathodes of light emitting elements of a plurality of pixel units within the display area. In the display area, the cathodes of the light emitting elements of the plurality of pixel units arranged in the first direction Y may be of an integral structure. The display cathode and the bezel cathode can be of an integral structure. The bezel cathode is electrically connected to a first power supply line structure 41 in the bezel area to realize circuit conduction.

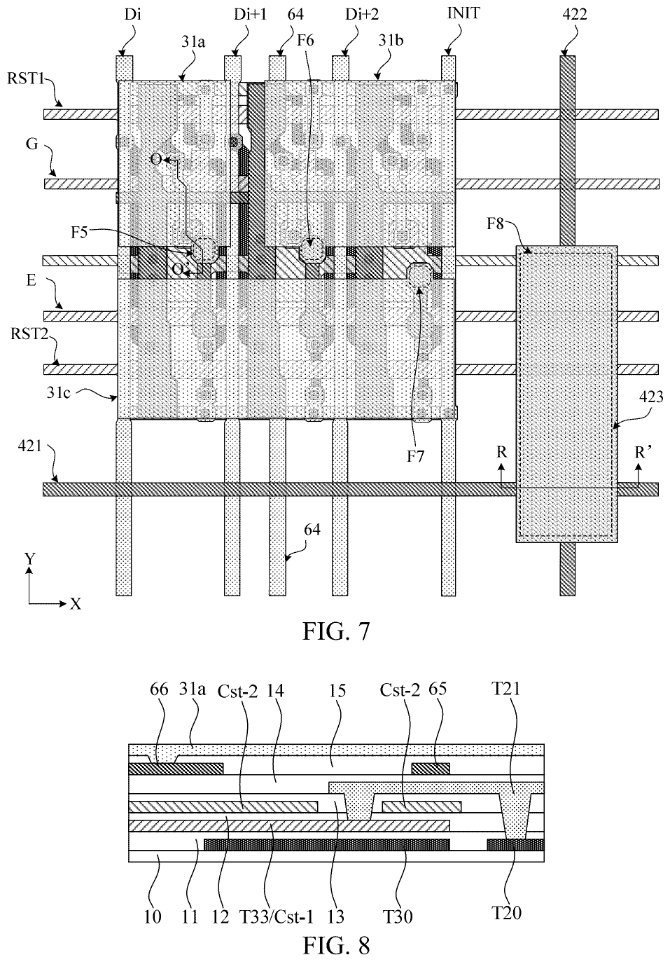

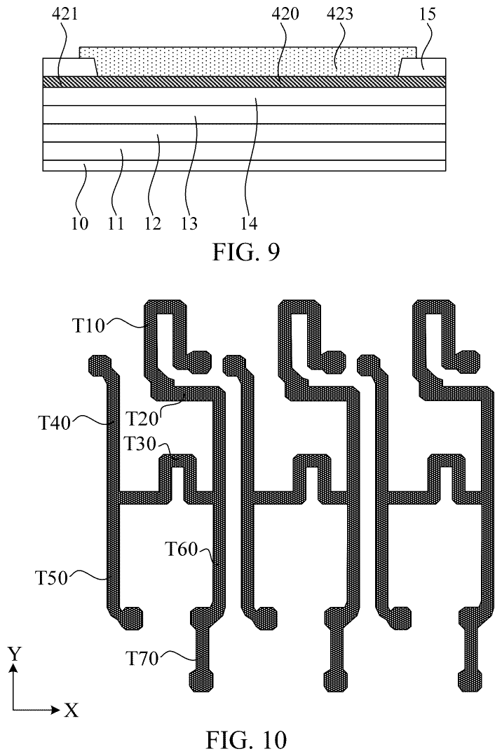

FIG. 7 is a schematic partial plan view of a display area according to at least one embodiment of the present disclosure. FIG. 8 is a schematic partial cross-sectional view along a O-O′ direction in FIG. 7. FIG. 9 is a schematic partial sectional view along an R-R′ direction in FIG. 7. FIG. 7 illustrates a planar structure of one pixel unit of the display area, in which one pixel unit may include three sub-pixels, for example, a first sub-pixel P1, a second sub-pixel P2, and a third sub-pixel P3.

In some exemplary implementation modes, as shown in FIG. 7, the pixel circuits of the three sub-pixels are sequentially arranged in the second direction X. In the second direction X, the pixel circuit of the first sub-pixel P1 is located between a data line Di and a data line Di+1 and is electrically connected to the data line Di. The pixel circuit of the second sub-pixel P2 is located between the data line Di+1 and a data line Di+2 and is electrically connected to the data line Di+1. The pixel circuit of the third sub-pixel P3 is located between the data line Di+2 and an initial signal line INIT, and is electrically connected to the data line Di+2. An anode 31a of a light emitting element of the first sub-pixel P1, an anode 31b of a light emitting element of the second sub-pixel P2, and an anode 31c of a light emitting element of the third sub-pixel P3 may be arranged in a delta-shaped form. However, this embodiment is not limited thereto.

In some exemplary implementation modes, as shown in FIGS. 7 to 9, in a plane perpendicular to the display substrate, the display substrate may include a semiconductor layer, a first conductive layer, a second conductive layer, a third conductive layer, a fourth conductive layer, and an anode layer that are sequentially arranged on the base substrate 10. In some examples, a first insulating layer 11 is provided between the semiconductor layer and the first conductive layer, a second insulating layer 12 is provided between the first conductive layer and the second conductive layer, a third insulating layer 13 is provided between the second conductive layer and the third conductive layer, a fourth insulating layer 14 is provided between the third conductive layer and the fourth conductive layer, and a fifth insulating layer 15 is provided between the fourth conductive layer and the anode layer. In some examples, the first insulating layer 11 to the fourth insulating layer 14 may be inorganic insulating layers, and the fifth insulating layer 15 may be an organic insulating layer. However, this embodiment is not limited thereto. In some examples, a pixel definition layer, an organic light emitting layer, a cathode and an encapsulation layer are further provided on a side of the anode layer away from the base substrate 10.

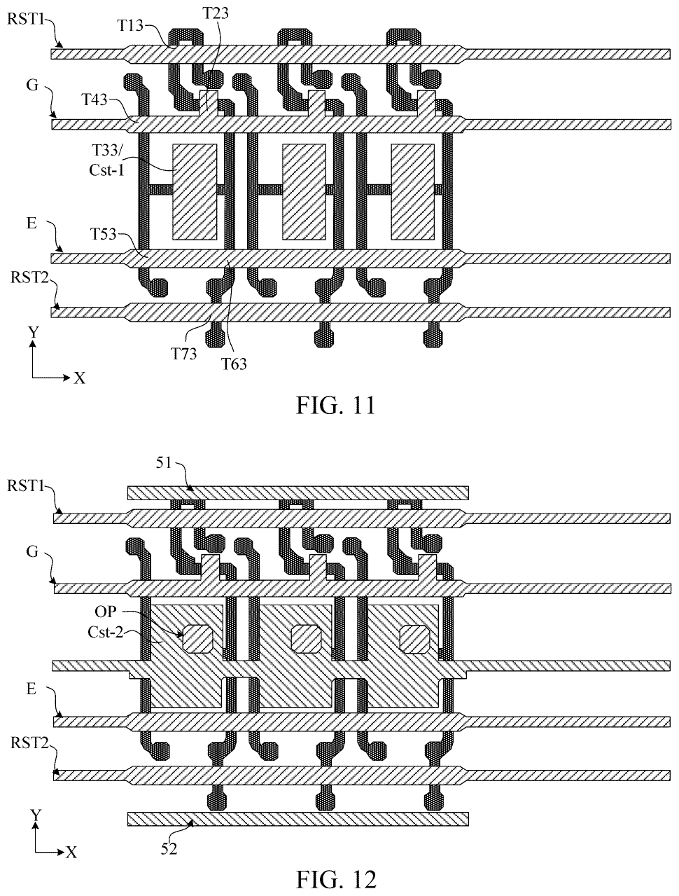

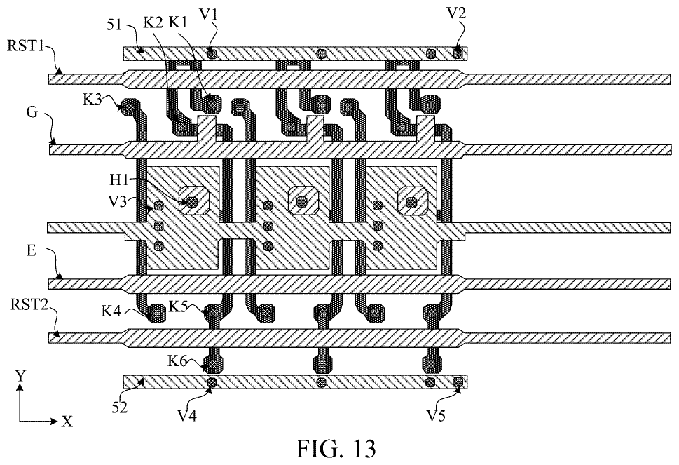

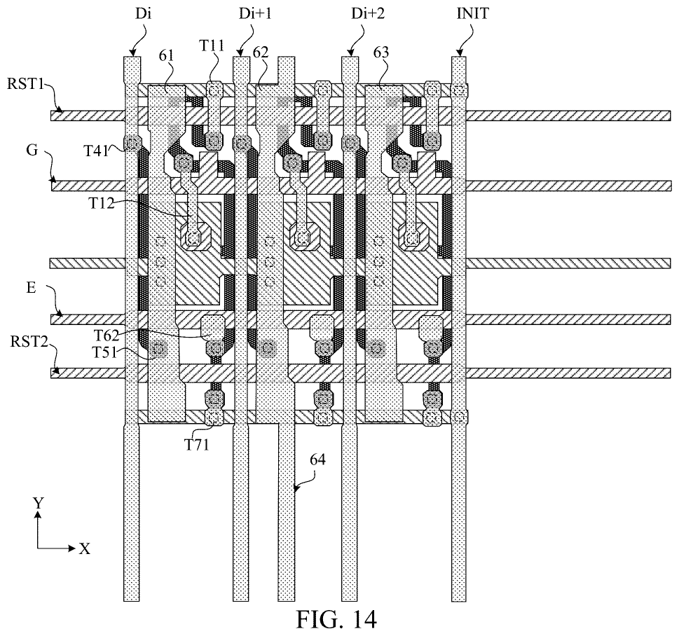

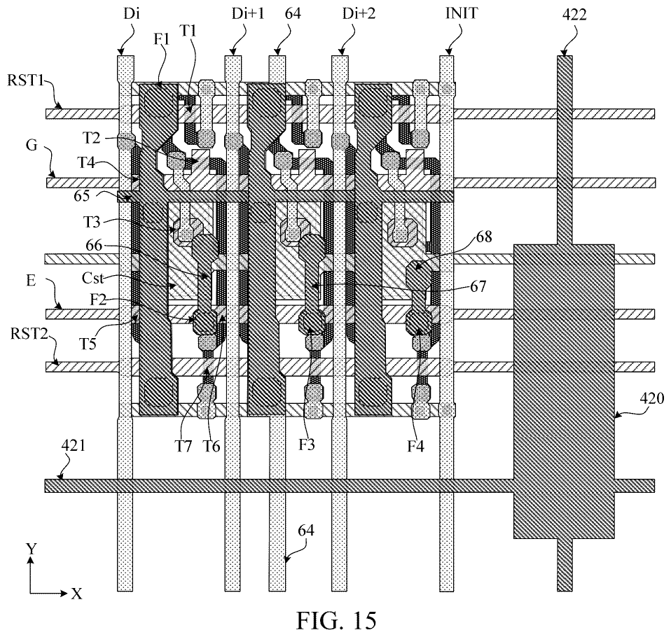

FIG. 10 is a schematic partial plan view of a display area after a semiconductor layer is formed according to at least one embodiment of the present disclosure. FIG. 11 is a schematic partial plan view of a display area after a first conductive layer is formed according to at least one embodiment of the present disclosure. FIG. 12 is a schematic partial plan view of a display area after a second conductive layer is formed according to at least one embodiment of the present disclosure. FIG. 13 is a schematic partial plan view of a display area after a third insulating layer is formed according to at least one embodiment of the present disclosure. FIG. 14 is a schematic partial plan view of a display area after a third conductive layer is formed according to at least one embodiment of the present disclosure. FIG. 15 is a schematic partial plan view of a display area after a fourth conductive layer is formed according to at least one embodiment of the present disclosure. Description is given below by mainly taking a planar structure of a pixel circuit of one sub-pixel as an example.

In some exemplary implementation modes, as shown in FIG. 10, the semiconductor layer of the display area may include active layers of a plurality of transistors of a plurality of pixel circuits, for example, a first active layer T10 of the first reset transistor T1, a second active layer T20 of the threshold compensation transistor T2, a third active layer T30 of the drive transistor T3, a fourth active layer T40 of the data writing transistor T4, a fifth active layer T50 of the first light emitting control transistor T5, a sixth active layer T60 of the second light emitting control transistor T6, and a seventh active layer T70 of the second reset transistor T7. The first active layer T10 to the seventh active layer T70 of a pixel circuit may be of an interconnected integral structure.

In some exemplary implementations, a material of the semiconductor layer may include, for example, polysilicon. An active layer may include at least one channel region and a plurality of doped regions. The channel region may not be doped with an impurity, and has characteristics of a semiconductor. The plurality of doped regions may be on two sides of the channel region and be doped with impurities, and thus have conductivity. The impurities may be changed according to a type of a transistor. In some examples, a doped region of the active layer may be interpreted as a source or a drain of a transistor. A part of the active layer between the transistors may be interpreted as a wiring doped with an impurity, and may be used for electrically connecting the transistors.

In some exemplary implementation modes, as shown in FIG. 11, the first conductive layer of the display area may include a scan line G, a light emitting control line E, a first reset control line RST1, a second reset control line RST2, and gates of a plurality of transistors of the pixel circuit (e.g., a gate T13 of the first reset transistor T1, a gate T23 of the threshold compensation transistor T2, a gate T33 of the drive transistor T3, a gate T43 of the data writing transistor T4, a gate T53 of the first light emitting control transistor T5, a gate T63 of the second light emitting control transistor T6, and a gate T73 of the second reset transistor T7). The scan line G, the light emitting control line E, the first reset control line RST1 and the second reset control line RST2 all extend in the second direction X. In the first direction Y, the first reset control line RST1, the scan line G, the light emitting control line E, and the second reset control line RST2 are arranged sequentially.

In some exemplary implementation modes, as shown in FIG. 11, a first electrode Cst-1 of the storage capacitor Cst and the gate T33 of the drive transistor T3 may be an integral structure. The scan line G, the gate T43 of the data writing transistor T4, and the gate T23 of the threshold compensation transistor T2 may be of an integral structure. The light emitting control line E, the gate T53 of the first emitting control transistor T5, and the gate T63 of the second emitting control transistor T6 may be of an integral structure. The first reset control line RST1 and the gate T13 of the first reset transistor T1 may be of an integral structure. The second reset control line RST2 and the gate T73 of the second reset transistor T7 may be of an integral structure. However, this embodiment is not limited thereto.

In some exemplary implementation modes, as shown in FIG. 12, the second conductive layer of the display area may include a second electrode Cst-2 of the storage capacitor Cst of the pixel circuit, a first initial connection line 51 and a second initial connection line 52. In the second direction X, second electrodes Cst-2 of storage capacitors Cst of adjacent pixel circuits may be of an integral structure. An orthographic projection of the second electrode Cst-2 of the storage capacitor Cst on the base substrate is located between an orthographic projection of the scan line G on the base substrate and an orthographic projection of the light emitting control line E on the base substrate. There is an overlapping region between the orthographic projection of the second electrode Cst-2 of the storage capacitor Cst on the base substrate and an orthographic projection of a first electrode Cst-1 on the base substrate. An opening OP is provided on the second electrode Cst-2, the opening OP exposes a second insulating layer covering the first electrode Cst-1, and the orthographic projection of the first electrode Cst-1 on the base substrate includes an orthographic projection of the opening OP on the base substrate.

In some examples, the opening OP is configured to accomodate a subsequently formed second via H1 that is located within the opening OP and exposes the first electrode Cst-1, so that the second electrode of the subsequently formed first reset transistor T1 is electrically connected to the first electrode Cst-1. The first initial connection line 51 and the second initial connection line 52 each extend in the second direction X. In the first direction Y, the first initial connection line 51 is located on a side of the first reset control line RST1 away from the scan line G, and the second initial connection line 52 is located on a side of the second reset control line RST2 away from the light emitting control line E. However, this embodiment is not limited thereto.

In some exemplary implementation modes, as shown in FIG. 13, a plurality of vias are provided on the third insulating layer 13 of the display area, which may include, for example, a plurality of first vias V1 to V5, a second via H1, and a plurality of third vias K1 to K6. The third insulating layers 13 in the plurality of first vias V1 to V5 are etched away to expose a surface of the second conductive layer. The third insulating layer 13 and the second insulating layer 12 in the second via H1 are etched away to expose a surface of the first conductive layer. The third insulating layer 13, the second insulating layer 12, and the first insulating layer 11 in the plurality of third vias K1 to K6 are etched away to expose a surface of the semiconductor layer.

In some exemplary implementation modes, as shown in FIG. 14, the third conductive layer of the display area may include a plurality of data lines (e.g., data lines Di, Di+1, and Di+2), an initial signal line INIT, first sub-power supply connection blocks (e.g., first sub-power supply connection blocks 61, 62, and 63), a third connection line 64, and first electrodes and second electrodes of a plurality of transistors of the pixel circuit (e.g., a first electrode T11 and a second electrode T12 of the first reset transistor T1, a first electrode T41 of the data writing transistor T4, a first electrode T51 of the first light emitting control transistor T5, a second electrode T62 of the second light emitting control transistor T6, and a first electrode T71 of the second reset transistor T7). The plurality of data lines and the initial signal line INIT extend in the first direction Y and are arranged sequentially in the second direction X.

In some exemplary implementation modes, as shown in FIGS. 13 and 14, the first electrode T11 of the first reset transistor T1 is electrically connected to a first doped region the first active layer T10 through a third via K1, and is also electrically connected to the first initial connection line 51 through a first via V1. The second electrode T12 of the first reset transistor T1 is electrically connected to a second doped region of the first active layer T10 through a third via K2, and is also electrically connected to the first electrode Cst-1 of the storage capacitor Cst through the second via H1. The first electrode T41 of the data writing transistor T4 is electrically connected to a first doped region of the fourth active layer T40 through a third via K3. The first electrode T41 of the data writing transistor T4 and the data line Di may be of an integral structure. The first electrode T51 of the first light emitting control transistor T5 is electrically connected to a first doped region of the fifth active layer T50 through the third via K4. The second electrode T62 of the second light emitting control transistor T6 is electrically connected to a second doped region of the sixth active layer T60 through a third via K5. The first electrode T71 of the second reset transistor T7 is electrically connected to a first doped region of the seventh active layer T70 through a third via K6, and is also electrically connected to the second initial connection line 52 through a first via V4. The initial signal line INIT is electrically connected to the first initial connection line 51 through a first via V2 and to the second initial connection line 52 through a first via V5. In this example, electrical connection between the initial signal line INIT and the plurality of pixel circuits is achieved by the first initial connection line 51 and the second initial connection line 52.

In some exemplary implementation modes, as shown in FIGS. 13 and 14, the first sub-power supply connection block 61 may be electrically connected to the second electrode Cst-2 of the storage capacitor Cst through a plurality of first vias V3 (e.g., three first vias arranged in the first direction Y). The first electrode T51 of the first light emitting control transistor T5 and the first sub-power supply connection block 61 may be of an integral structure. Similarly, the first sub-power supply connection blocks 62 and 63 may each be electrically connected to second electrodes of corresponding storage capacitors. The first sub-power supply connection blocks 61, 62 and 63 are independent of each other and the first sub-power supply connection block 62 and the third connection line 64 may be of an integral structure. The third connection line 64 may extend in the first direction Y. The third connection line 64 is configured to achieve electrical connection between first sub-power supply connection blocks of adjacent pixel units.

In some exemplary implementation modes, as shown in FIG. 15, the fourth conductive layer of the display area may include a second sub-power supply connection block 65, a plurality of connection electrodes (e.g., connection electrodes 66, 67 and 68), a first sub-auxiliary electrode 420, a fourth connection line 421, and a fifth connection line 422. In some examples, the connection electrode 66 may be electrically connected to the second electrode T62 of the second light emitting control transistor T6 of a pixel circuit through a fourth via F2. A connection electrode 67 may be electrically connected to a second electrode of a second light emitting control transistor of another pixel circuit through a fourth via F3, and a connection electrode 68 may be electrically connected to a second electrode of a second light emitting control transistor of a third pixel circuit through a fourth via F4.

In some exemplary implementation modes, as shown in FIG. 15, the second sub-power supply connection block 65 may be electrically connected to the first sub-power supply connection blocks 61, 62 and 63 through a plurality of fourth vias F1. An orthographic projection of the second sub-power supply connection block 65 on the base substrate overlaps with each of orthographic projections of the three first sub-power supply connection blocks 61, 62 and 63 on the base substrate. In this example, a power supply connection block of the display area corresponds to one pixel unit. For example, the power supply connection block may include one second sub-power supply connection block and three first sub-power supply connection blocks electrically connected to the second sub-power supply connection block. Within the display area, an electrical connection between adjacent power supply connection blocks may be achieved through a third connection line 64 to transmit the second voltage signal VDD. Transmission of the second voltage signal VDD between adjacent pixel units in the display area can be achieved by the third connection line 64 and the second electrode Cst-2 of the storage capacitor Cst. In some examples, the third connection line 64 may be electrically connected to the second connection line within the bezel area to achieve electrical connection with the second power supply line structure within the bezel area.

In some exemplary implementation modes, as shown in FIG. 15, the fourth connection line 421 extends in the second direction X and the fifth connection line 422 extends in the first direction Y. An orthographic projection of the first sub-auxiliary electrode 420 on the base substrate may be rectangular. The first sub-auxiliary electrode 420, the fourth connection line 421 and the fifth connection line 422 may be of an integral structure. Within the display area, the fifth connection line 422 is electrically connected to the first sub-auxiliary electrode 420 adjacent in the first direction Y, and the fourth connection line 421 is electrically connected to the first sub-auxiliary electrode 420 adjacent in the second direction X. In some examples, the fifth connection line 422 may extend to the bezel area in the first direction Y, and the fourth connection line 421 may be electrically connected to the first connection line of the bezel area to achieve electrical connection between the first sub-auxiliary electrode 420 and the first power supply line structure 41 within the bezel area.

In some exemplary implementation modes, as shown in FIG. 7, an anode layer of the display area may include anodes (e.g., anodes 31a, 31b and 31c) of light emitting elements of a plurality of sub-pixels and a second sub-auxiliary electrode 423. In some examples, the anode 31a may be electrically connected to the connection electrode 66 through a fifth via F5, the anode 31b may be electrically connected to the connection electrode 67 through a fifth via F6, and the anode 31c may be electrically connected to the connection electrode 68 through a fifth via F7. The second sub-auxiliary electrode 423 may be electrically connected to the first sub-auxiliary electrode 420 through a fifth via F8. An orthographic projection of the second sub-auxiliary electrode 423 on the base substrate may be rectangular. The orthographic projection of the second sub-auxiliary electrode 423 on the base substrate may include the orthographic projection of the first sub-auxiliary electrode 420 on the base substrate. In this example, the auxiliary electrode may be formed by the electrical connection between the first sub-auxiliary electrode 420 and the second sub-auxiliary electrode 423 which are stacked. The auxiliary electrode provided by double-layer electrodes can reduce the resistance and improve the signal transmission effect.

In some exemplary implementation modes, the first conductive layer, the second conductive layer, the third conductive layer, and the fourth conductive layer may be made of a metal material such as any one or more of silver (Ag), copper (Cu), aluminum (Al), and molybdenum (Mo), or an alloy material of the above metals, such as an aluminum-neodymium alloy (AlNd) or a molybdenum-niobium alloy (MoNb), may be of a single-layer structure or a multi-layer composite structure such as Mo/Cu/Mo, etc. The first insulating layer 11, the second insulating layer 12, the third insulating layer 13, and the fourth insulating layer 14 may be made of any one or more of Silicon Oxide (SiOX), Silicon Nitride (SiNX), and Silicon Oxynitride (SiON), and may be a single layer, a multi-layer, or a composite layer. The fifth insulating layer 15 may be made of an organic material, such as polyimide, acrylic, or polyethylene terephthalate. However, this embodiment is not limited thereto.

In some exemplary implementation modes, the light emitting element of the sub-pixel may include an anode, a pixel definition layer, an organic light emitting layer and a cathode. The pixel definition layer has a pixel opening exposing the anode, and the organic light emitting layer is formed in the pixel opening. The organic light emitting layer of the light emitting element is connected to the anode, the cathode is connected to the organic light emitting layer, and the organic light emitting layer is driven by the anode and the cathode to emit light with a corresponding color. An encapsulation layer may be provided at a side of the cathode away from the base substrate. The encapsulation layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is provided between the first encapsulation layer and the third encapsulation layer to ensure that external water vapor cannot enter the light emitting layer.

In some exemplary implementation modes, the organic light emitting layer may include a Hole Injection Layer (HIL), a Hole Transport Layer (HTL), an Electron Block Layer (EBL), Emitting Layer (EML), a Hole Block Layer (HBL), an Electron Transport Layer (ETL), and an Electron Injection Layer (EIL) which are stacked. In some examples, hole injection layers and electron injection layers of all sub-pixels may be connected together to be a common layer, hole transport layers and electron transport layers of all the sub-pixels may be connected together to be a common layer, hole block layers of all the sub-pixels may be connected together to be a common layer, and emitting layers and electron block layers of adjacent sub-pixels may be overlapped slightly, or may be isolated. However, this embodiment is not limited thereto.

In some exemplary implementation modes, the pixel definition layer may be made of an organic material, such as polyimide, acrylic, or polyethylene terephthalate. The anode of the light emitting element may be made of a reflective material such as a metal, and the cathode may be made of semi-transparent and semi-reflective material. However, this embodiment is not limited thereto. In some examples, the anode of the light emitting element may be made of a transparent conductive material such as indium tin oxide (ITO) or indium zinc oxide (IZO), and the cathode may be made of any one or more of magnesium (Mg), silver (Ag), aluminum (Al), copper (Cu), and lithium (Li), or an alloy made of any one or more of the above metals.

In some exemplary implementation modes, the cathode of the display substrate may include a bezel cathode located in the bezel area BB and a display cathode located in the display area AA. The bezel cathode and the display cathode are disposed in a same layer.

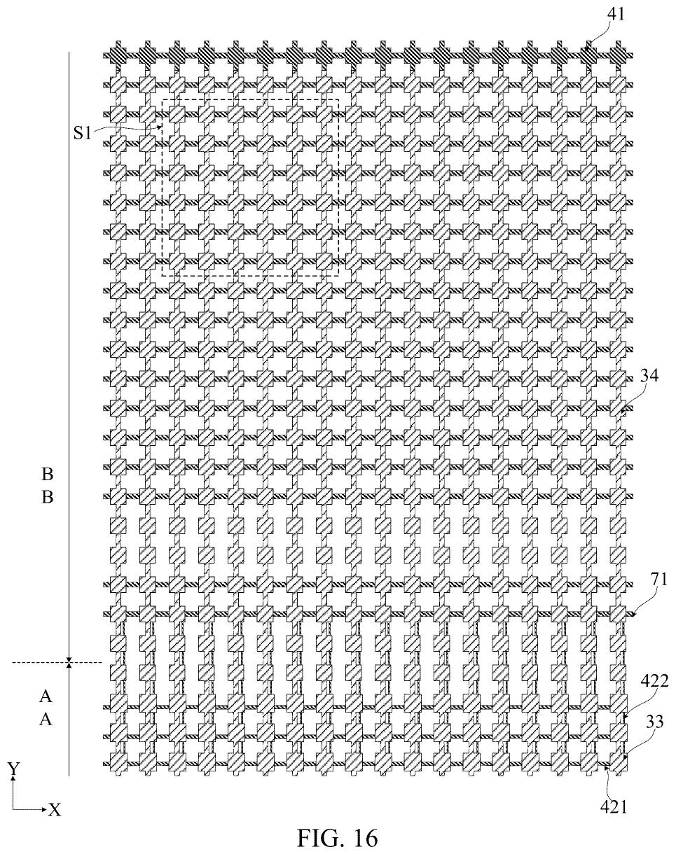

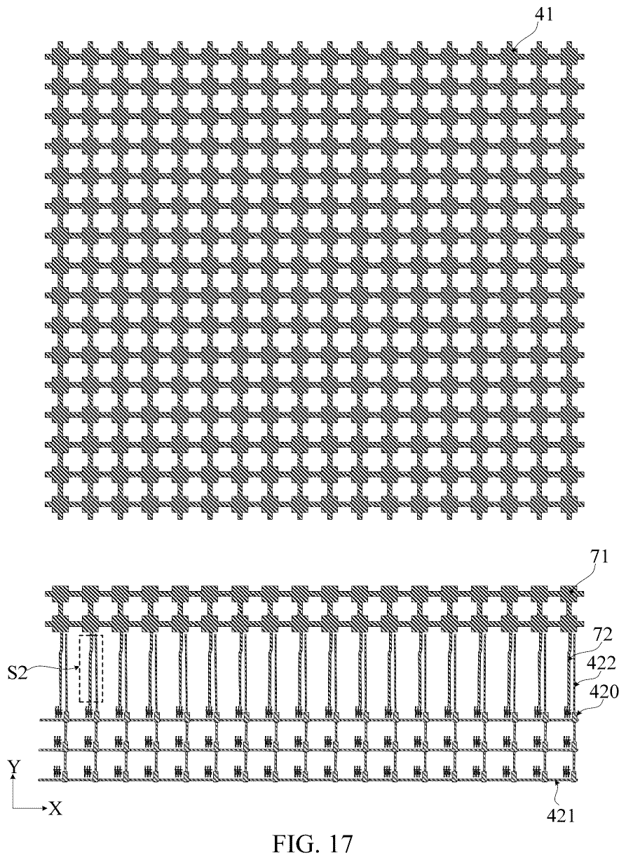

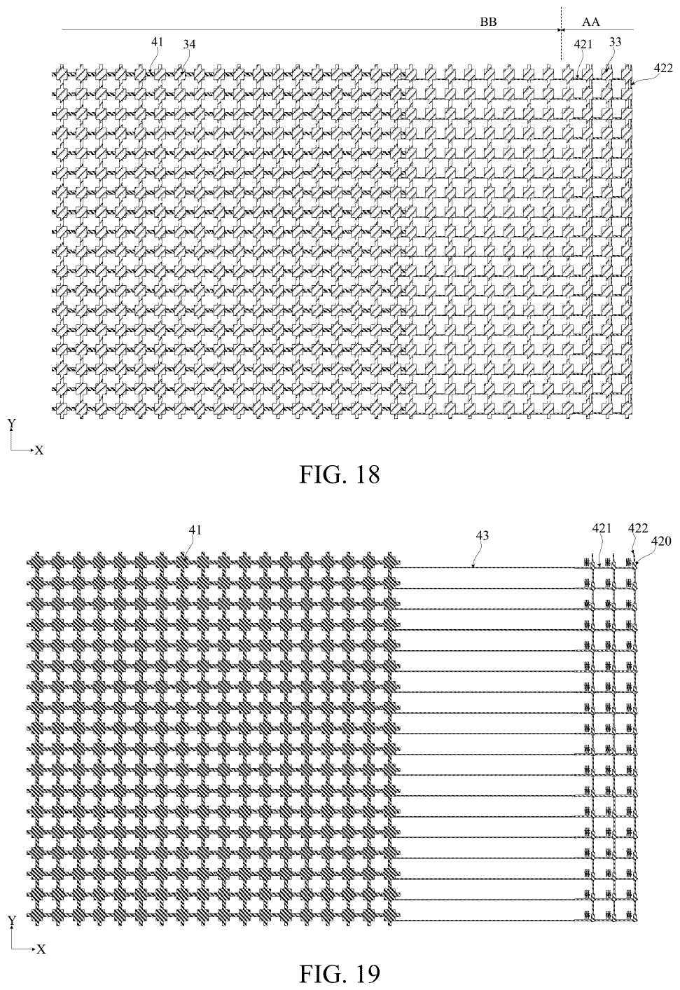

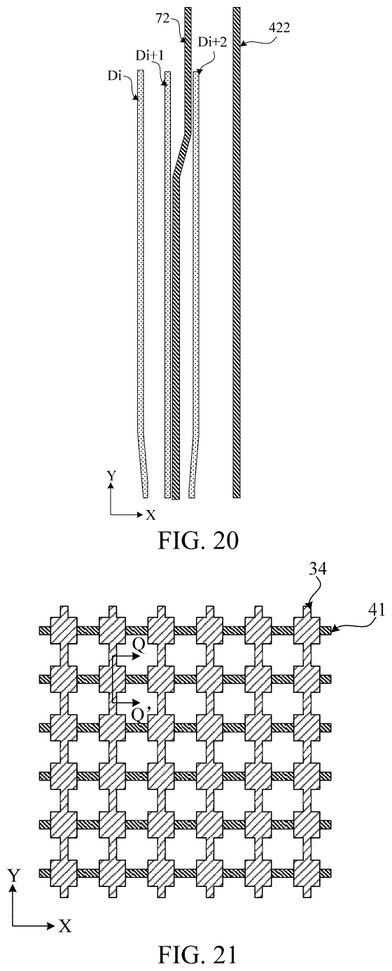

FIG. 16 is a schematic partial view of a region A1 in FIG. 2. FIG. 17 is a schematic diagram of the fourth conductive layer in FIG. 16. FIG. 18 is a schematic partial view of a region A2 in FIG. 2. FIG. 19 is a schematic diagram of the third conductive layer in FIG. 18. Planar structures of the fourth conductive layer and the cathode of the display substrate are schematically shown in FIGS. 16 and 18. FIG. 20 is a schematic partial enlarged view of a region S2 in FIG. 17.

In some exemplary implementation modes, as shown in FIGS. 16 to 19, the first power supply line structure 41 of the bezel area BB has a plurality of first openings, and the bezel cathode 34 of the bezel area BB has a plurality of second openings. The first power supply line structure 41 may include a plurality of first repetition units arranged in an array and connected to each other. The plurality of first repetition units are connected to form a mesh such that the first power supply line structure 41 has the plurality of first openings. The bezel cathode 34 may include a plurality of second repetition units arranged in an array and connected to each other in the first direction Y. The plurality of second repetition units arranged in the second direction X are not connected to each other. The plurality of second repetition units may be connected to form a plurality of columns such that the bezel cathode 34 has the plurality of second openings. By patterning the first power supply line structure 41 and the bezel cathode 34 of the bezel area BB, the light transmittance of the bezel area BB can be improved. A total width of the first power supply line structure 41 is not limited in this embodiment.

In some exemplary implementation modes, as shown in FIGS. 16 to 19, the display cathode 33 of the display area AA may include a plurality of third repetition units. The plurality of third repetition units arranged in the first direction Y may be connected to each other. The plurality of third repetition units arranged in the second direction X are not connected to each other. In the upper bezel of the bezel area BB, the plurality of second repetition units arranged in the first direction Y are connected to each other and are connected to the plurality of third repetition units arranged in the first direction Y in the display area AA. In the left bezel of the bezel area BB, the second repetition units of the bezel cathode 34 are not connected to the third repetition units of the display area AA. In some examples, shape, size and connection relationship of the third repetition units of the display cathode 33 are substantially the same as the shape, size and connection relationship of the second repetition units of the bezel cathode 34. However, this embodiment is not limited thereto. For example, the shape of the third repetition units of the display cathode may be different from the shape of the second repetition units of the bezel cathode. Alternatively, the display cathode may be of a full-face structure without an opening.

In some exemplary implementation modes, as shown in FIGS. 6, 16, and 18, an orthographic projection of the third repetition units of the display cathode 33 of the display area AA on the base substrate may cover orthographic projections of one pixel unit and one auxiliary electrode on the base substrate. However, this embodiment is not limited thereto.

In some exemplary implementation modes, as shown in FIGS. 16 and 17, the upper bezel of the bezel area BB is further provided with a second power supply line structure 71. The second power supply line structure 71 is located on a side of the first power supply line structure 41 close to the display area AA. The second power supply line structure 71 and the first power supply line structure 41 may be disposed in a same layer. The second power supply line structure 71 may be electrically connected to a power supply connection block of the display area AA through a second connection line 72. For example, the second connection line 72 may be electrically connected to the third connection line 64 within the display area AA. In some examples, the second connection line 72 is located on a side of the third connection line 64 away from the base substrate. For example, the third connection line 64 is located in the third conductive layer and the second connection line 72 is located in the fourth conductive layer. In some examples, the fifth connection line 422 electrically connected to the first sub-auxiliary electrode 420 may extend in the first direction Y to a position within the upper bezel close to the second power supply line structure 71. The fifth connection line 422 has no electrical connection with the second power supply line structure 71.

In some exemplary implementation modes, as shown in FIG. 17, the second power supply line structure 71 may include a plurality of fourth repetition units arranged in an array and connected to each other. In some examples, shape, size and connection relationship of the fourth repetition units of the second power supply line structure 71 may be substantially the same as the shape, size and connection relationship of the first repetition units of the first power supply line structure 41. As shown in FIG. 16, an orthographic projection of the second repetition units on the base substrate overlaps with an orthographic projection of the fourth repetition units on the base substrate. However, this embodiment is not limited thereto. For example, the shape of the fourth repetition units of the second power supply line structure 71 may be different from the shape of the first repetition units of the first power supply line structure 41. In this example, the second power supply line structure 71 of the bezel area BB may have a patterned design to further improve the light transmittance of the bezel area BB.

In some exemplary implementation modes, as shown in FIG. 20, the second connection line 72 and the fifth connection line 422 are located in the fourth conductive layer. A plurality of data lines (e.g., data lines Di, Di+1, and Di+2) are located in the third conductive layer. The second connection line 72 has a straight part and a bent part. In the bezel area, the second connection line 72 is located on a side of the fifth connection line 422 in the second direction X. An orthographic projection of the second connection line 72 on the base substrate does not overlap with an orthographic projection of the plurality of data lines on the base substrate. For example, the orthographic projection of the second connection line 72 on the base substrate may be located between orthographic projections of the data line Di+1 and the data line Di+2 on the base substrate. An orthographic projection of a virtual extension line of the straight part of the second connection line 72 on the base substrate overlaps with an orthographic projection of the data line on the base substrate. For example, the second connection line 72 includes a first straight part, a bent part and a second straight part connected sequentially. An orthographic projection of a virtual extension line of the first straight part on the base substrate overlaps with an orthographic projection of the data line Di+2 on the base substrate, and an orthographic projection of a virtual extension line of the second straight part on the base substrate overlaps with an orthographic projection of the data line Di+1 on the base substrate. In this example, the second connection line is set to be staggered from the data lines of adjacent layers, which can avoid signal interference.

In some exemplary implementation modes, as shown in FIGS. 18 and 19, a plurality of first connection lines 43 are provided in the bezel area BB (e.g., the left bezel). The plurality of first connection lines 43 may extend in the second direction X and be arranged in the first direction Y. The first power supply line structure 41 of the bezel area BB may be electrically connected to an auxiliary electrode in the display area AA through the first connection lines 43. In some examples, the first power supply line structure 41, a first sub-auxiliary electrode 420 of the auxiliary electrode, the first connection line 43 and the fourth connection line 421 may be of an integral structure. For example, the first connection line 43 of the bezel area BB is electrically connected to the fourth connection line 421 of the display area AA thereby achieving an electrical connection between the first power supply line structure 41 and the first sub-auxiliary electrode 420. Within the display area AA, the first sub-auxiliary electrode 420 can be electrically connected to the display cathode 33 through a second sub-auxiliary electrode 423, thereby achieving an electrical connection between the first power supply line structure 41 and the display cathode 33. As shown in FIG. 18, in the bezel area BB, an orthographic projection of the bezel cathode 34 on the base substrate overlaps with an orthographic projection of the first connection line 43 on the base substrate. However, this embodiment is not limited thereto. In some exemplary implementation modes, as shown in FIG. 18, there may be no electrical connection between the bezel cathode 34 of the left bezel and the display cathode 33 of the display area AA. By electrically connecting the bezel cathodes 34 of the left bezel and the right bezel to the first power supply line structure 41, resistance of the first power supply line structure 41 can be reduced. However, this embodiment is not limited thereto.

In some exemplary implementation modes, the plurality of first sub-auxiliary electrodes 420 of the display area may be arranged in an array and electrically connected by the fourth connection line 421 and the fifth connection line 422. The plurality of second sub-auxiliary electrodes 423 of the display area may be arranged in an array and independent of each other. However, this embodiment is not limited thereto. For example, the plurality of second sub-auxiliary electrodes of the display area may be electrically connected by a sixth connection line extending in the first direction and a seventh connection line extending in the second direction.

In this exemplary implementation mode, the first power supply line structure 41 may be directly electrically connected to the display cathode 33 of the display area AA through the bezel cathodes 34 of the upper bezel and the lower bezel, and may also be electrically connected to the auxiliary electrodes of the display area AA through the first connection lines 43 of the left bezel and the right bezel, and then electrically connected to the display cathode 33 through the auxiliary electrode, thereby realizing a circuit path between the first power supply line structure 41 and the display cathode 33. However, this embodiment is not limited thereto.

In some exemplary implementation modes, as shown in FIGS. 16 and 18, in the bezel area BB, an orthographic projection of the first power supply line structure 41 on the base substrate may include the orthographic projection of the bezel cathode 34 on the base substrate, in an overlapping region between the first power supply line structure 41 and the bezel cathode 34. In this way, the loss of light transmittance in the bezel area can be reduced.

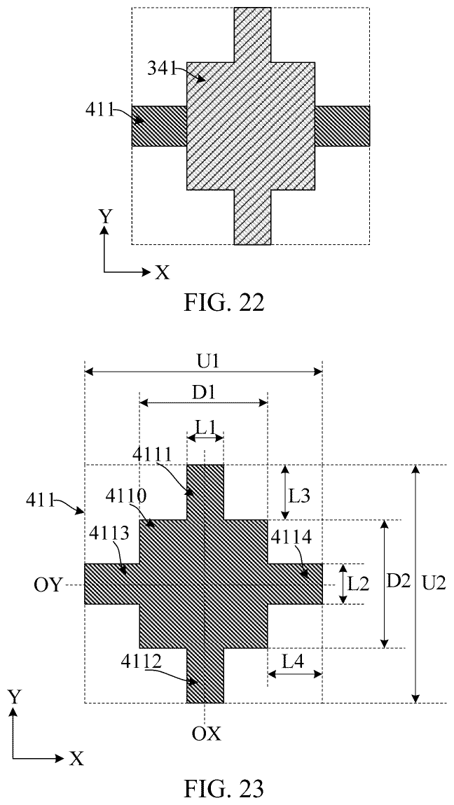

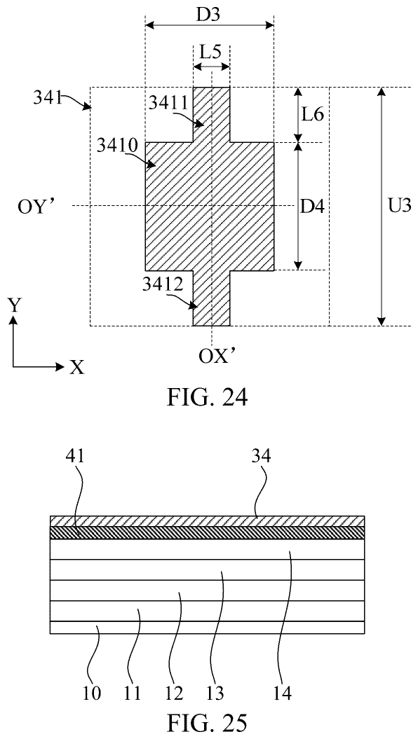

FIG. 21 is a schematic enlarged view of the region S1 in FIG. 16. FIG. 22 is a schematic plan view of a first repetition unit and a second repetition unit according to at least one embodiment of the present disclosure. FIG. 23 is a schematic plan view of a first repetition unit according to at least one embodiment of the present disclosure. FIG. 24 is a schematic plan view of a second repetition unit according to at least one embodiment of the present disclosure.

In some exemplary implementation modes, as shown in FIGS. 21 and 22, an orthographic projection of the first repetition units 411 of the first power supply line structure 41 on the base substrate may include an orthographic projection of the second repetition units 341 of the bezel cathode 34 on the base substrate.

In some exemplary implementation modes, as shown in FIG. 23, a first repetition unit 411 of the first power supply line structure 41 may include a first main body 4110, a first connection bridge 4111 and a second connection bridge 4112 formed by extending from opposite sides of the first main body 4110 in the first direction Y, and a third connection bridge 4113 and a fourth connection bridge 4114 formed by extending from opposite sides of the first main body 4110 in the second direction X. In some examples, an orthographic projection of the first main body 4110 on the base substrate may be rectangular, for example, may be square. Orthographic projections of the first connection bridge 4111 and the second connection bridge 4112 on the base substrate may be rectangular. For example, lengths of the first connection bridge 4111 and the second connection bridge 4112 in the first direction Y may be greater than those in the second direction X. Orthographic projections of the third connection bridge 4113 and the fourth connection bridge 4114 on the base substrate may be rectangular. For example, lengths of the third connection bridge 4113 and the fourth connection bridge 4114 in the first direction Y may be smaller than those in the second direction X. However, this embodiment is not limited thereto. For example, an orthographic projection of the first main body on the base substrate may be in other shapes, such as a circle or an ellipse. Orthographic projections of the first connection bridge, the second connection bridge, the third connection bridge, and the fourth connection bridge on the base substrate may be in other shapes such as wavy lines. Orthographic projections of the first main body, the first connection bridge, the second connection bridge, the third connection bridge and the fourth connection bridge on the base substrate may be identical or partially identical or all different in shape.

In some exemplary implementation modes, as shown in FIG. 21, the first connection bridge 4111 and the second connection bridge 4112 of the first repetition unit 411 may be connected to adjacent first repetition units in the first direction Y, and the third connection bridge 4113 and the fourth connection bridge 4114 may be connected to adjacent first repetition units in the second direction X.

In some exemplary implementation modes, as shown in FIG. 23, the first connection bridge 4111 and the second connection bridge 4112 of the first repetition unit 411 may be substantially symmetrical about a first center line OY of the first main body 4110 in the first direction Y, and the third connection bridge 4113 and the fourth connection bridge 4114 may be substantially symmetrical about a second center line OX of the first main body 4110 in the second direction X. In this example, the first repetition unit 411 may be symmetrical with respect to the first center line OY and may also be symmetrical with respect to the second center line OX. However, this embodiment is not limited thereto.

In some exemplary implementation modes, as shown in FIG. 24, the second repetition unit 341 includes a second main body 3410, a fifth connection bridge 3411 and a sixth connection bridge 3412 formed by extending from opposite sides of the second main body 3410 in the first direction Y. In some examples, an orthographic projection of the second main body 3410 on the base substrate may be rectangular, for example, may be square. Orthographic projections of the fifth connection bridge 3411 and the sixth connection bridge 3412 on the base substrate may be rectangular. For example, lengths of the fifth connection bridge 3411 and the sixth connection bridge 3412 in the first direction Y may be greater than those in the second direction X. However, this embodiment is not limited thereto. For example, an orthographic projection of the second main body on the base substrate may be in other shapes, such as a circle or an ellipse. Orthographic projections of the fifth connection bridge and the sixth connection bridge on the base substrate may be in other shapes such as wavy lines. Orthographic projections of the second main body, the fifth connection bridge and the sixth connection bridge on the base substrate may be identical or partially identical or all different in shape.

In some exemplary implementation modes, as shown in FIG. 21, the fifth connection bridge 3411 and the sixth connection bridge 3412 of the second repetition unit 341 may be connected to adjacent second repetition units 341 in the first direction Y.

In some exemplary implementation modes, as shown in FIG. 12, the fifth connection bridge 341 land the sixth connection bridge 3412 of the second repetition unit 341 may be substantially symmetrical with respect to a third center line OY′ of the second main body 3410 in the first direction Y. In this example, the second repetition unit 341 may be substantially symmetrical with respect to a fourth center line OX′ in the second direction X, and may also be substantially symmetrical with respect to the third center line OY′ in the first direction Y. In some examples, the third center line OY′ may coincide with the first center line OY, and the fourth center line OX′ may coincide with the second center line OX. However, this embodiment is not limited thereto.

FIG. 25 is a schematic partial cross-sectional view along a Q-Q′ direction in FIG. 21. In some exemplary implementation modes, as shown in FIGS. 21 to 25, the bezel cathode 34 is located on a side of the first power supply line structure 41 away from the base substrate 10 in a plane perpendicular to the display substrate. The first power supply line structure 41 is located in the fourth conductive layer. The second main body 3410 of the second repetition unit 341 of the bezel cathode 34 is in direct contact with the first main body 4110 of the first repetition unit 411 of the first power supply line structure 41, the fifth connection bridge 3411 of the second repetition unit 341 is in direct contact with the first connection bridge 4111 of the first repetition unit 411, and the sixth connection bridge 3412 of the second repetition unit 341 is in direct contact with the second connection bridge 4112 of the first repetition unit 411. The third connection bridge 4113 and the fourth connection bridge 4114 of the first repetition unit 411 are not in contact with the second repetition unit 341. In some examples, an orthographic projection of the first main body 4110 of the first repetition unit 411 on the base substrate may include an orthographic projection of the second main body 3410 of the second repetition unit 341 on the base substrate. For example, the orthographic projection of the second main body 3410 of the second repetition unit 341 on the base substrate may coincide with the orthographic projection of the first main body 4110 of the first repetition unit 411 on the base substrate. An orthographic projection of the first connection bridge 4111 of the first repetition unit 411 on the base substrate may include an orthographic projection of the fifth connection bridge 3441 of the second repetition unit 341 on the base substrate. For example, the orthographic projection of the first connection bridge 4111 of the first repetition unit 411 on the base substrate and the orthographic projection of the fifth connection bridge 3441 of the second repetition unit 341 on the base substrate may coincide. An orthographic projection of the second connection bridge 4112 of the first repetition unit 411 on the base substrate may include an orthographic projection of the sixth connection bridge 3412 of the second repetition unit 341 on the base substrate. For example, the orthographic projection of the second connection bridge 4112 of the first repetition unit 411 on the base substrate and the orthographic projection of the sixth connection bridge 3412 of the second repetition unit 341 on the base substrate may coincide. However, this embodiment is not limited thereto.

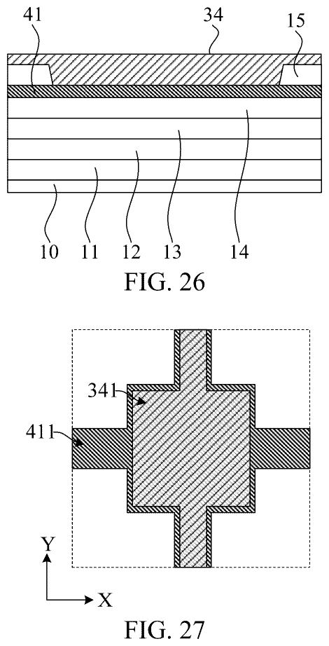

FIG. 26 is another partial cross-sectional schematic diagram taken along a Q-Q′ direction in FIG. 21. In some exemplary implementation modes, as shown in FIGS. 21 to 24 and 26, the bezel cathode 34 is located on a side of the first power supply line structure 41 away from the base substrate 10 in a plane perpendicular to the display substrate. The first power supply line structure 41 is located in the fourth conductive layer. The second main body 3410 of the second repetition unit 341 of the bezel cathode 34 may be in direct contact with the first main body 4110 of the first repetition unit 411 of the first power supply line structure 41, the fifth connection bridge 3411 of the second repetition unit 341 is not in contact with the first connection bridge 4111 of the first repetition unit 411, and the sixth connection bridge 3412 of the second repetition unit 341 is not in contact with the second connection bridge 4112 of the first repetition unit 411. For example, the fifth insulating layer 15 is disposed between the fifth connection bridge 3411 and the sixth connection bridge 3412 of the second repetition unit 341 and the first repetition unit 411. In this example, an orthographic projection of the connection region of the bezel cathode 34 and the first power supply line structure 41 on the base substrate 10 may be within an orthographic projection of the first main body 4110 of the first power supply line structure 41 on the base substrate 10. However, this embodiment is not limited thereto.

In some exemplary implementation modes, as shown in FIG. 23, the length of the first repetition unit 411 in the second direction X is denoted as U1 and the length thereof in the first direction Y is denoted as U2. In some examples, U1 and U2 can be roughly the same. For example, U1=U2=25400/P, where P is the resolution of the display substrate. The length of the first main body 4110 of the first repetition unit 411 in the second direction X is denoted as D1 and the length thereof in the first direction Y is denoted as D2. The first connection bridge 4111 and the second connection bridge 4112 are symmetrical about the first center line OY. The length of the first connection bridge 4111 and the second connection bridge 4112 may be substantially the same in the first direction Y and the length thereof may be substantially the same in the second direction X. For example, the length of the first connection bridge 4111 in the first direction Y is denoted as L3 and the length thereof in the second direction X is denoted as L1. The third connection bridge 4113 and the fourth connection bridge 4114 are symmetrical about the second center line OX. The third connection bridge 4113 and the fourth connection bridge 4114 may have substantially the same length in the first direction Y and may have substantially the same length in the second direction X. For example, the length of the third connection bridge 4113 in the first direction Y is denoted as L2 and the length thereof in the second direction X is denoted as L4.

In some exemplary implementation modes, as shown in FIG. 24, the length of the second repetition unit 341 in the first direction Y is denoted U3. The length of the second repetition unit 341 in the second direction X is the length of the second main body 3410 in the second direction X, for example, is denoted as D3. The length of the second main body 3410 in the first direction Y is denoted as D4. The fifth connection bridge 3411 and the sixth connection bridge 3412 are substantially symmetrical about the third center line OY′. The lengths of the fifth connection bridge 3411 and the sixth connection bridge 3412 may be substantially the same in the first direction Y and the lengths thereof in the second direction X may be substantially the same. For example, the length of the fifth connection bridge 3411 in the first direction Y is denoted as L6 and the length thereof in the second direction X is denoted as L5.

In some exemplary implementation modes, U3 and U2 may be substantially the same, D3 may be less than or equal to D1, D4 may be less than or equal to D2, L5 may be less than or equal to L1, and L6 may be greater than or equal to L3.

In some exemplary implementation modes, taking the light transmittance of the display area as about 71% and the light transmittance required for the bezel area as TR as an example, the length L2 of the third connection bridge 4113 of the first repetition unit 411 in the first direction Y may be determined according to the following formula.

$$L 2 = [ ( 1 - TR / 0.71 ) * {( 25 \; 400 / P )}^{2} - D 1 * D 2 - 2 L 1 * L 3 ] / ( 2 * L 4 ) ;$$

Herein, P is the resolution of the display substrate, D1 is the length of the first main body 4110 of the first repetition unit 411 in the second direction X, D2 is the length of the first main body 4110 in the first direction Y, L1 is the length of the first connection bridge 4111 in the second direction X, L3 is the length of the first connection bridge 4111 in the first direction Y, and L4 is the length of the third connection bridge 4113 in the second direction X.

In some exemplary implementation modes, the length U2 in the first direction Y and the length U1 in the second direction X of the first repetition unit 411 may be determined according to the resolution of the display substrate. For example, if the resolution of the display substrate is about 40 to 100, the range of U1 and U2 may be about 254 μm to 635 um.

In some exemplary implementation modes, the length D2 of the first main body 4110 in the first direction Y and the length D1 in the second direction X may be determined according to the preparation process and the resolution of the display substrate. For example, D1 and D2 can range from about 50 μm to 635 um.

In some exemplary implementation modes, L3 and L4 may be calculated according to U1, U2, D1 and D2 in a case in which the first repetition unit 411 is symmetrical about the first center line OY and symmetrical about the second center line OX. For example, L4=(U1−D1)/2; L3=(U2−D2)/2. In some examples, the smaller the value of L1, the better the light transmission effect. For example, limited by the mask accuracy, the minimum value of L1 can be about 70 um.

In some exemplary implementation modes, the resolution P of the display substrate is about 83, the light transmittance required for the display area is about 71%, and the light transmittance TR required for the bezel area is about 40%. U1 and U2 for the first repetition unit are substantially the same, for example, U1=U2=306 um. According to the light transmittance required for the display area, it can be calculated that the pixel size of the display area is about 100*100, that is, D3 and D4 for the second repetition unit are the same and are about 100. Based on the mask boundary having a single side of 35, the first repetition units D1 and D2 can be obtained to be approximately the same, for example, may be about 170 um. According to the symmetry of the first repetition unit, it can be calculated that L3=L4=(306−170)/2=68 um. Taking L1=70 um as an example, we can get L2=18 um according to the above calculation formula for L2.

The display substrate according to this exemplary embodiment can enhance the light transmittance of the bezel area by patterning the first power supply line structure and the bezel cathode of the bezel area, thereby realizing a transparent bezel.

In some exemplary implementation modes, as shown in FIGS. 16 and 18, the third repetition unit of the display cathode of the display area may include a third main body, a ninth connection bridge and a tenth connection bridge formed by extending from opposite sides of the third main body in the first direction Y. The structure of the third main body, the ninth connection bridge and the tenth connection bridge of the third repetition unit can be described with reference to the description of the second main body, the fifth connection bridge and the sixth connection bridge of the second repetition unit and therefore will not be described here. However, this embodiment is not limited thereto. For example, the dimensions of the third main body of the third repetition unit and the second main body of the second repetition unit may be substantially the same, and the lengths of the ninth and tenth connection bridges of the third repetition unit in the second direction may be smaller than the lengths of the fifth and sixth connection bridges of the second repetition unit in the second direction.

FIG. 27 is another schematic plan view of a first repetition unit and a second repetition unit according to at least one embodiment of the present disclosure. In some exemplary implementation modes, as shown in FIG. 27, orthographic projections of the second repetition units 341 on the base substrate are within orthographic projections of the first repetition units 411 on the base substrate. In this example, the length of the second main body of the second repetition unit 341 in the second direction X is smaller than the length of the first main body of the first repetition unit 411 in the second direction X, and the length of the second main body of the second repetition unit 341 in the first direction Y is smaller than the length of the first main body of the first repetition unit 411 in the first direction Y. The lengths of the fifth and sixth connection bridges of the second repetition unit 341 in the second direction X are smaller than the lengths of the first connection bridge and the second connection bridge of the first repetition unit 411 in the second direction X.

Rest of the structure of the display substrate according to this exemplary embodiment may be referred to descriptions of the aforementioned embodiments, and will not be repeated here. The structure (or the method) shown in this embodiment may be combined with structures (or methods) shown in other embodiments as appropriate.

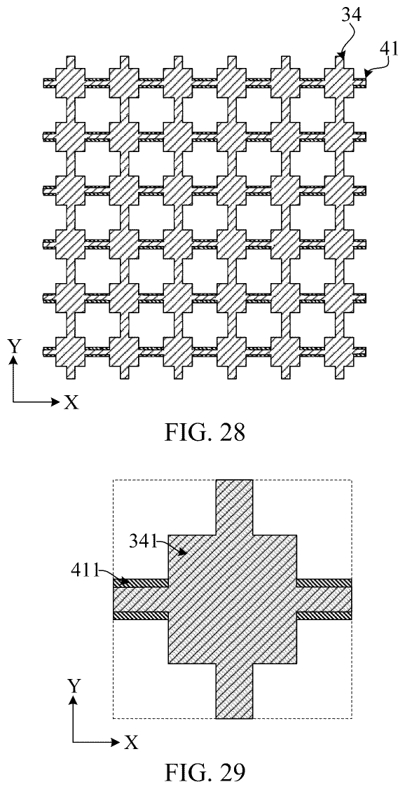

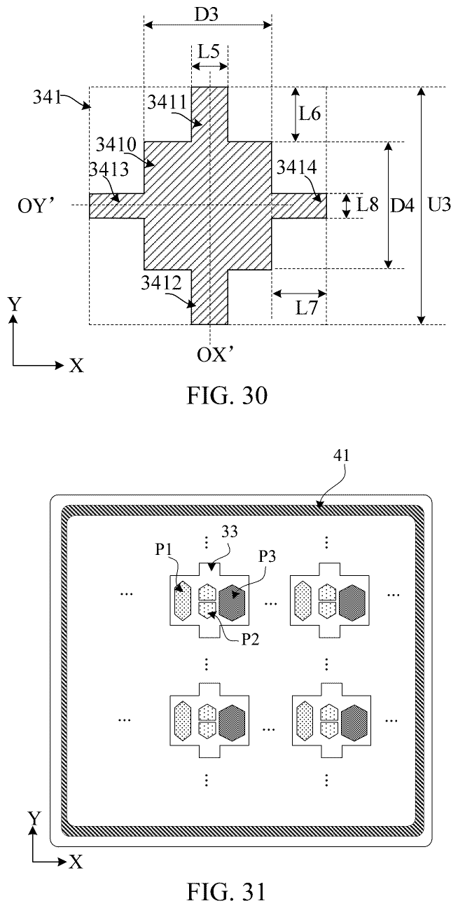

FIG. 28 is another schematic plan view of a bezel area according to at least one embodiment of the present disclosure. FIG. 29 is another schematic plan view of a first repetition unit and a second repetition unit according to at least one embodiment of the present disclosure. FIG. 30 is another schematic plan view of a second repetition unit according to at least one embodiment of the present disclosure.

In some exemplary implementation modes, as shown in FIGS. 28-30, the second repetition unit 341 may include a second main body 3410, a fifth connection bridge 3411 and a sixth connection bridge 3412 formed by extending from opposite sides of the second main body 3410 in the first direction Y, and a seventh connection bridge 3413 and an eighth connection bridge 3414 formed by extending from opposite sides of the second main body 3410 in the second direction X. In some examples, orthographic projections of the seventh connection bridge 3413 and the eighth connection bridge 3414 on the base substrate may be rectangular. For example, the lengths of the seventh connection bridge 3413 and the eighth connection bridge 3414 in the first direction Y may be smaller than that in the second direction X. However, this embodiment is not limited thereto.

In some exemplary implementation modes, as shown in FIGS. 28-30, the fifth connection bridge 341 land the sixth connection bridge 3412 of the second repetition unit 341 may be connected to adjacent second repetition units 341 in the first direction Y. The seventh connection bridge 3413 and the eighth connection bridge 3414 of the second repetition unit 341 may be connected to adjacent second repetition units 341 in the second direction X. An orthographic projection of the seventh connection bridge 3413 on the base substrate may be within an orthographic projection of the third connection bridge 4113 of the first repetition unit 411 on the base substrate, and an orthographic projection of the eighth connection bridge 3414 on the base substrate may be within an orthographic projection of the fourth connection bridge 4114 of the first repetition unit 341 on the base substrate.

In some exemplary implementation modes, as shown in FIG. 30, the seventh connection bridge 3413 and the eighth connection bridge 3414 may be substantially symmetrical with respect to the fourth center line OX′ of the second main body 3410 in the second direction X. The length of the seventh connection bridge 3413 in the first direction Y is denoted as L8, and the length of the seventh connection bridge 3413 in the second direction X is denoted as L7. In some examples, L7 may be greater than or equal to L4, and L8 may be less than or equal to L2. However, this embodiment is not limited thereto.

In some exemplary implementation modes, the third repetition unit of the display cathode may include a third main body, a ninth connection bridge and a tenth connection bridge formed by extending from opposite sides of the third main body in the first direction, and an eleventh connection bridge and a twelfth connection bridge formed by extending from opposite sides of the third main body in the second direction. The structure of the third main body, the ninth connection bridge, the tenth connection bridge, the eleventh connection bridge, and the twelfth connection bridge of the third repetition unit can be described with reference to the description of the second main body, the fifth connection bridge, the sixth connection bridge, the seventh connection bridge, and the eighth connection bridge of the second repetition unit and therefore will not be described here.

Rest of the structure of the display substrate according to this exemplary embodiment may be referred to descriptions of the aforementioned embodiments, and will not be repeated here. The structure (or the method) shown in this embodiment may be combined with structures (or methods) shown in other embodiments as appropriate.

In some exemplary implementation modes, as shown in FIGS. 6, 16, and 18, the shape, size, and connection relationship of the repetition units of the display cathode 33 and the bezel cathode 34 are substantially the same. The shape of the main body of the repetition unit of the display cathode and the bezel cathode can be determined according to the arrangement of a plurality of sub-pixels within the pixel unit. For example, if the three sub-pixels in the pixel unit are arranged in a manner like a Chinese character “a”, an orthographic projection of the second main body of the second repetition unit on the base substrate may be approximately square. In this example, an orthographic projection of the first main body of the first repetition unit on the base substrate may be substantially square. However, this embodiment is not limited thereto.

FIG. 31 is another schematic partial view of a cathode according to at least one embodiment of the present disclosure. In some exemplary implementation modes, as shown in FIG. 31, the first sub-pixel P1, the two second sub-pixels P2, and the third sub-pixel P3 of the display area may be arranged sequentially along the second direction X, and the two second sub-pixels P2 may be arranged sequentially along the first direction Y. In this example, orthographic projections of the third main body of the third repetition unit of the display cathode and the second main body of the second repetition unit of the bezel cathode on the base substrate may be in a shape of a rectangle, and the length of the rectangle in the first direction Y may be smaller than that in the second direction X. An orthographic projection of the first main body of the first repetition unit of the first power supply line structure 41 on the base substrate may be rectangular. Rest of the structure of the display substrate according to this exemplary embodiment may be referred to descriptions of the aforementioned embodiments, and will not be repeated here. The structure (or the method) shown in this embodiment may be combined with structures (or methods) shown in other embodiments as appropriate.

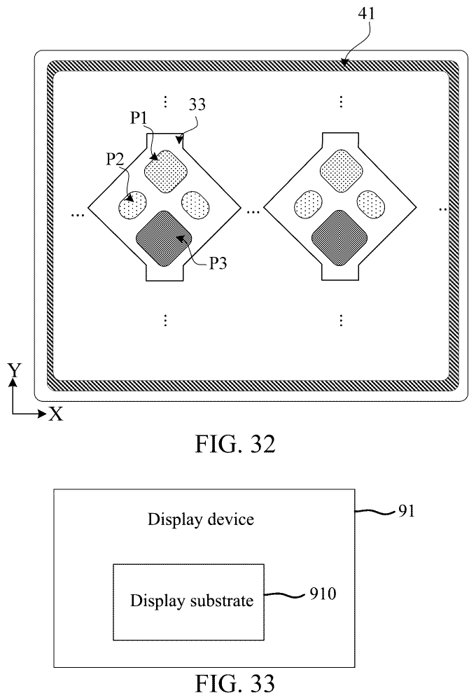

FIG. 32 is another schematic partial view of a cathode according to at least one embodiment of the present disclosure. In some exemplary implementation modes, as shown in FIG. 32, the first sub-pixel P1, the two second sub-pixels P2, and the third sub-pixel P3 of the display area may be arranged in a diamond-shaped manner. In this example, orthographic projections of the third main body of the third repetition unit of the display cathode and the second main body of the second repetition unit of the bezel cathode on the base substrate may be, for example, in a shape of a rhombus. An orthographic projection of the first main body of the first repetition unit of the first power supply line structure 41 on the base substrate may be in a shape of a rhombus. Rest of the structure of the display substrate according to this exemplary embodiment may be referred to descriptions of the aforementioned embodiments, and will not be repeated here. The structure (or the method) shown in this embodiment may be combined with structures (or methods) shown in other embodiments as appropriate.

The structures of the display substrates of the above embodiments are only some exemplary illustrations. In some exemplary implementation modes, the corresponding structure may be changed according to actual needs. For example, the first power supply line structure may use the fourth conductive layer and the anode layer in a double-layer wiring mode. For another example, the power supply connection block and the auxiliary electrode can use the third conductive layer in a single-layer wiring mode. As another example, the display substrate may not be provided with a fourth conductive layer. As another example, orthographic projections of the first repetition unit and the second repetition unit on the base substrate may coincide. However, this embodiment is not limited thereto.

FIG. 33 is a schematic diagram of a display device according to at least one embodiment of the present disclosure. As shown in FIG. 33, a display device 91 is provided in this embodiment, which includes a display substrate 910 in the aforementioned embodiments. In some examples, the display substrate 910 may be an OLED display substrate or a QLED display substrate. The display device 91 may be any product or component with a display function, such as a mobile phone, a tablet computer, a television, a display, a laptop computer, a digital photo frame, and a navigator. However, this embodiment is not limited thereto.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate comprising a display area and a bezel area located around the display area;
a plurality of light emitting elements located in the display area, at least one of the light emitting elements comprises an anode, an organic light emitting layer, and a cathode arranged sequentially in a direction away from the base substrate;
a first power supply line structure electrically connected to the cathode and located in the bezel area;
the first power supply line structure has at least one first opening; the cathode comprises a bezel cathode located in the bezel area, and the bezel cathode has at least one second opening; and
an orthographic projection of the first power supply line structure on the base substrate at least partially overlaps with an orthographic projection of the bezel cathode on the base substrate, and an orthographic projection of the at least one first opening on the base substrate at least partially overlaps with an orthographic projection of the at least one second opening on the base substrate.

2. The display substrate according to claim 1, wherein the first power supply line structure comprises a plurality of first repetition units arranged in an array and connected to each other.

3. The display substrate according to claim 2, wherein each first repetition unit comprises: a first main body, a first connection bridge and a second connection bridge formed by extending from opposite sides of the first main body in a first direction, and a third connection bridge and a fourth connection bridge formed by extending from the opposite sides of the first main body in a second direction; and the first direction intersects with the second direction.

4. The display substrate according to claim 3, wherein each of the first connection bridge and the second connection bridge has a length in the first direction is greater than a length in the second direction, and each of the third connection bridge and the fourth connection bridge has a length in the first direction less than a length in the second direction.

5. The display substrate according to claim 3, wherein a length of the first repetition unit in the first direction is substantially the same as a length of the first repetition unit in the second direction.

6. The display substrate according to claim 3, wherein orthographic projections of the first main body, the first connection bridge, the second connection bridge, the third connection bridge, and the fourth connection bridge on the base substrate are all rectangular; or
wherein the first connection bridge and the second connection bridge are substantially symmetrical with respect to a center line of the first main body in the first direction; and
the third connection bridge and the fourth connection bridge are substantially symmetrical with respect to a center line of the first main body in the second direction.

7. (canceled)

8. The display substrate according to claim 6, wherein the length of the third connection bridge in the first direction is determined according to the following equation:
$$L 2 = [ ( 1 - TR / 0.71 ) * {( 25 \; 400 / P )}^{2} - D 1 * D 2 - 2 L 1 * L 3 ] / ( 2 * L 4 ) ;$$
where TR is a light transmittance required by the bezel area, P is a resolution of the display substrate, D1 is a length of the first main body in the second direction, D2 is a length of the first main body in the first direction, L1 is a length of the first connection bridge in the second direction, L3 is a length of the first connection bridge in the first direction, and L4 a the length of the third connection bridge in the second direction.

9. The display substrate according to claim 3, wherein the bezel cathode is located on a side of the first power supply line structure away from the base substrate; an orthographic projection of a connection area between the bezel cathode and the first power supply line structure on the base substrate is within an orthographic projection of the first main body of the first power supply line structure on the base substrate.

10. The display substrate according to claim 3, wherein the bezel cathode comprises: a plurality of second repetition units; the plurality of second repetition units arranged in the first direction are connected to each other;
in an overlapping region between the bezel cathode and the first power supply line structure, an orthographic projection of the first repetition units on the base substrate comprises an orthographic projection of the second repetition units on the base substrate.

11. The display substrate according to claim 10, wherein each second repetition unit comprises a second main body, a fifth connection bridge and a sixth connection bridge formed by extending from opposite sides of the second main body in the first direction.

12. The display substrate according to claim 11, wherein the fifth connection bridge and the sixth connection bridge are substantially symmetrical with respect to a center line of the second repetition unit in the first direction; or
orthographic projections of the second main body, the fifth connection bridge, and the sixth connection bridge on the base substrate are all rectangular: or
the second repetition unit further comprises: a seventh connection bridge and an eighth connection bridge formed by extending from opposite sides of the second main body in the second direction; and the plurality of second repetition units are connected in a mesh.

13-14. (canceled)

15. The display substrate according to claim 10, wherein the cathode further comprises: a display cathode located in the display area, the display cathode comprises: a plurality of third repetition units arranged in an array; shape, size and connection relationship of the third repetition units of the display cathode are substantially the same as shape, size and connection relationship of the second repetition units of the bezel cathode.

16. The display substrate according to claim 15, wherein each third repetition unit comprises a third main body, a ninth connection bridge and a tenth connection bridge formed by extending from opposite sides of the third main body in the first direction; or
the display substrate further comprises: a plurality of auxiliary electrodes located in the display area and electrically connected to the plurality of third repetition units of the display cathode, the plurality of auxiliary electrodes are electrically connected to the first power supply line structure of the bezel area via a first connection line.

17. (canceled)

18. The display substrate according to claim 16, wherein the first connection line extends in the second direction, the first connection line is electrically connected to the first main body of the first power supply line structure; the bezel cathode is provided on a side of the first connection line away from the base substrate, and an orthographic projection of the first connection line on the base substrate overlaps with the orthographic projection of the bezel cathode on the base substrate; or
each auxiliary electrode comprises: a first sub-auxiliary electrode disposed in a same layer as the first power supply line structure, and a second sub-auxiliary electrode disposed in a same layer as the anode of the light emitting element, the first sub-auxiliary electrode is electrically connected to the second sub-auxiliary electrode; and the third repetition unit is electrically connected to the second sub-auxiliary electrode and the first sub-auxiliary electrode.

19. (canceled)

20. The display substrate according to claim 18, wherein in the display area, the plurality of first sub-auxiliary electrodes are arranged in an array and connected by a fourth connection line and a fifth connection line; the plurality of second sub-auxiliary electrodes are arranged in an array; an orthographic projection of the second sub-auxiliary electrodes on the base substrate covers an orthographic projection of the first sub-auxiliary electrodes on the base substrate.

21. The display substrate according to claim 20, wherein orthographic projections of the first sub-auxiliary electrodes and the second sub-auxiliary electrodes on the base substrate are all rectangular.

22. The display substrate according to claim 10, wherein the bezel area comprises an upper bezel provided with a second power supply line structure, the second power supply line structure comprises a plurality of fourth repetition units arranged in an array, shape, size and connection relationship of the fourth repetition units are substantially the same as the shape, size and connection relationship of the first repetition units;
the orthographic projection of the second repetition units on the base substrate overlaps with an orthographic projection of the fourth repetition units on the base substrate.

23. The display substrate according to claim 22, wherein the display area is provided with a plurality of power supply connection blocks; the second power supply line structure is electrically connected to the power supply connection blocks of the display area through a second connection line;
the second connection line has a straight part and a bent part, a plurality of data lines are provided on a side of the second connection line close to the base substrate, an orthographic projection of the second connection line on the base substrate does not overlap with an orthographic projection of the plurality of data lines on the base substrate, and an orthographic projection of a virtual extension line of the straight part of the second connection line on the base substrate overlaps with the orthographic projection of the data lines on the base substrate.

24. The display substrate according to claim 23, wherein each power supply connection block comprises a first sub-power supply connection block and a second sub-power supply connection block which are stacked and electrically connected to each other, an orthographic projection of the first sub-power supply connection block on the base substrate has a shape of a strip extending in the second direction, and an orthographic projection of the second sub-power supply connection block on the base substrate comprises the orthographic projection of the first sub-power supply connection block on the base substrate.

25. A display device, comprising the display substrate according to claim 1.
